(19) United States
(12) Patent Application Publication
(10) Pub. No.: US 2026/0033312 A1
(43) Pub. Date: Jan. 29, 2026

(54) STRUCTURES AND METHODS FOR THERMAL DISSIPATION IN DIES

(71) Applicant: ADEIA SEMICONDUCTOR BONDING TECHNOLOGIES INC., San Jose, CA (US)

(72) Inventors: Rajesh KATKAR, Milpitas, CA (US); Laura Wills MIRKARIMI, Sunol, CA (US); Gaius Gillman FOUNTAIN, Jr., Youngsville, NC (US); Cyprian Emeka UZOH, San Jose, CA (US); Belgacem HABA, Saratoga, CA (US)

(21) Appl. No.: 18/938,132

(22) Filed: Nov. 5, 2024

Related U.S. Application Data
(60) Provisional application No. 63/676,757, filed on Jul. 29, 2024.

(51) Int. Cl. H01L 23/00; H01L 23/31; H01L 23/367; H01L 23/522; H01L 23/528; H01L 23/532; H01L 25/16

(52) U.S. Cl. CPC H01L 24/08; H01L 23/5226; H01L 23/528; H01L 23/5283; H01L 23/53271; H01L 25/167; H01L 23/3185; H01L 23/3672; H01L 24/32; H01L 24/80; H01L 2224/08145; H01L 2224/32145; H01L 2224/80895; H01L 2224/80896; H01L 2924/19011

(57) ABSTRACT

Disclosed is a bonded structure including an element with a bonding surface, the bonding surface having a dielectric region and a first semiconductor region laterally spaced from the dielectric region. The bonded structure further includes a first die directly bonded to the dielectric region of the element without an intervening adhesive. The bonded structure further includes a second die having a second bonding surface having a second semiconductor region, the second semiconductor region being bonded to the first semiconductor region of the element without an intervening adhesive and without an intervening deposited dielectric material.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

The field relates to structures and methods for thermal dissipation in dies, such as semiconductor and other microelectronic dies.

### Description of the Related Art

Microelectronic bonded structures can be assembled for packaging by bonding a plurality of dies onto a host substrate (e.g., a die, a wafer, an interposer, etc.). Direct bonding generally, and hybrid bonding more specifically, can advantageously provide robust connections among the elements being bonded, and facilitate greater density of connections between electronic components. However, electronic components generate heat when in use, which can lead to higher temperatures in and around the elements being bonded. Efficient thermal dissipation remains an issue for microelectronic elements.

### BRIEF DESCRIPTION OF THE DRAWINGS

The detailed description is set forth with reference to the accompanying figures. The use of the same reference numbers in different figures indicates similar or identical items. Additionally, the use of reference numerals that increment by 100 with each figure (e.g., 250 in FIG. 2E, 350 in FIG. 3B, etc.) also indicate similar or identical items, unless otherwise specified.

For this discussion, the devices and systems illustrated in the figures are shown as having a multiplicity of components. Various implementations of devices and/or systems, as described herein, may include fewer components and remain within the scope of the disclosure. Alternatively, other implementations of devices and/or systems may include additional components, or various combinations of the described components, and remain within the scope of the disclosure.

These aspects and others will be apparent from the following description of preferred embodiments and the accompanying drawings, which are meant to illustrate and not to limit the invention, wherein:

FIG. 1A is a schematic side sectional view of two elements before being directly bonded, according to an embodiment.

FIG. 1B is a schematic side sectional view of the two elements of FIG. 1A after being directly bonded, according to an embodiment.

FIGS. 2A-2E present a series of schematic side sectional views that show a method by which a bonded structure can be formed to have a deposited dielectric bonding layer obstruct the flow of heat to the outside environs.

FIG. 3A is a schematic side sectional view of a bonded structure with two deposited dielectric bonding layers obstructing the flow of heat to a heat dissipative die.

FIGS. 3B and 3C present schematic side sectional views of two bonded structures without a deposited dielectric bonding layer obstructing the flow of heat to a heat dissipative die, according to various embodiments.

FIGS. 4A-4I present schematic side sectional views of various bonded structures with various geometries and configurations of direct thermal pathways, according to various embodiments.

FIGS. 5A-5F present a series of schematic side sectional views that show a method by which a bonded structure similar to the bonded structure shown in FIG. 3B is formed, according to an embodiment.

FIGS. 6A-6G present a series of schematic side sectional views that show a method by which a bonded structure similar to the bonded structure shown in FIG. 3C is formed, according to an embodiment.

FIGS. 7A-7C present a series of schematic side sectional views that show a method by which various bonded structures can be formed in which a dissipative feature is bonded to an overheating die with an intervening metallic bonding layer, according to various embodiments.

FIGS. 8A-8F present a series of schematic side sectional views that show a method by which a bonded structure similar to the bonded structure shown in FIG. 4I is formed, according to an embodiment.

### DETAILED DESCRIPTION

Active microelectronic elements generate heat when in use, which can lead to higher temperatures in and/or around the microelectronic elements. Elevated temperature in and/or around the microelectronic elements can damage the microelectronic elements (e.g. semiconductor devices within such microelectronic elements) or surrounding components and packaging structures. In some instances, the damage can be incremental, diminishing the element's usability by degrees. In some instances, the damage can be destructive, rendering the element unusable. Since many microelectronic elements are often electrically connected to other microelectronic elements in larger circuits, the damage to any microelectronic element can negatively impact other microelectronic elements to which the damaged microelectronic element is connected. The problem of overheated microelectronic elements can be magnified when microelectronic elements are packed more densely, which can be facilitated by using direct bonding and hybrid bonding techniques. The problem of overheated microelectronic elements can also be magnified when microelectronic elements are stacked in layers upon layers. Such layered stacking of active dies can trap heat in interior dies (e.g. dies located near the bottom of a die stack) without efficient means for heat dissipation. Heat generated in interior dies is further trapped by dielectric bonding material used to facilitate bonding between layers of dies. While the dielectric bonding material can facilitate robust and reliable bonding between layers of dies, the dielectric bonding material can also be thermally insulative, further trapping heat generated by internal dies. To efficiently dissipate heat away from active microelectronic elements, a thermal pathway can be built into the bonded structures of microelectronic elements. To efficiently dissipate heat away from internal active microelectronic elements, a vertical thermal pathway can be built into the layered bonded structures to carry heat between layers. Dummy dies comprising a bulk semiconductor material (e.g., silicon with no or comparatively few active devices or transistors) can be used to carry heat away from neighboring active dies. Dummy dies are effective heat dissipators because semiconductors, for example silicon, can conduct heat orders of magnitude more effectively than dielectric bonding materials, for example silicon dioxide or the like. However, the vertical thermal pathway can be obstructed if the dummy die is bonded to a deposited dielectric bonding material. A more effective vertical thermal pathway can be formed by reducing the thermally insulative effect of dielectric bonding materials. One mechanism for reducing the thermally insulative effect of dielectric bonding materials is to remove the dielectric bonding material where it is not necessary, instead bonding semiconductor layers directly to each other (although a thin native oxide layer may be present due to exposure to the environment). Another mechanism for reducing the thermally insulative effect of dielectric bonding materials is to embed conductive vias through the dielectric bonding material. The conductive vias, which can comprise copper, nickel, aluminum or the like, can conduct heat vertically across the bond interface, from one layer to another.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

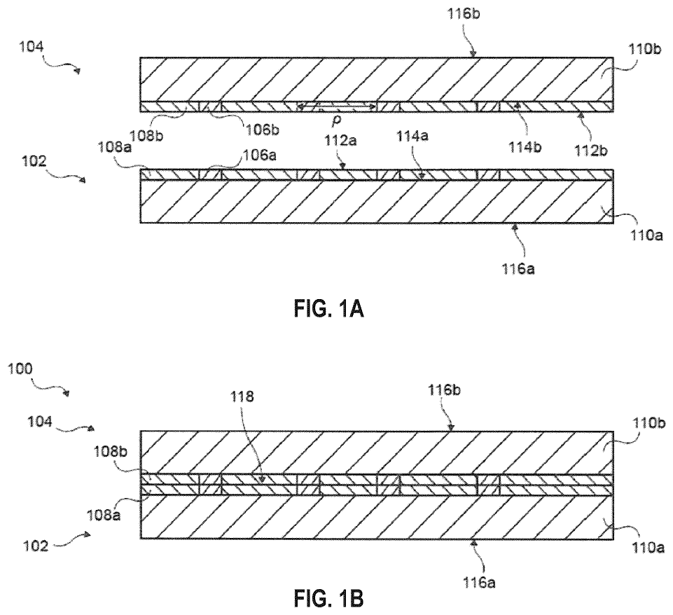

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO₃) or lithium niobate (LiNbO₃), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2 W), die-to-die (D2D), or die-to-wafer (D2 W) bonding processes. In W2 W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

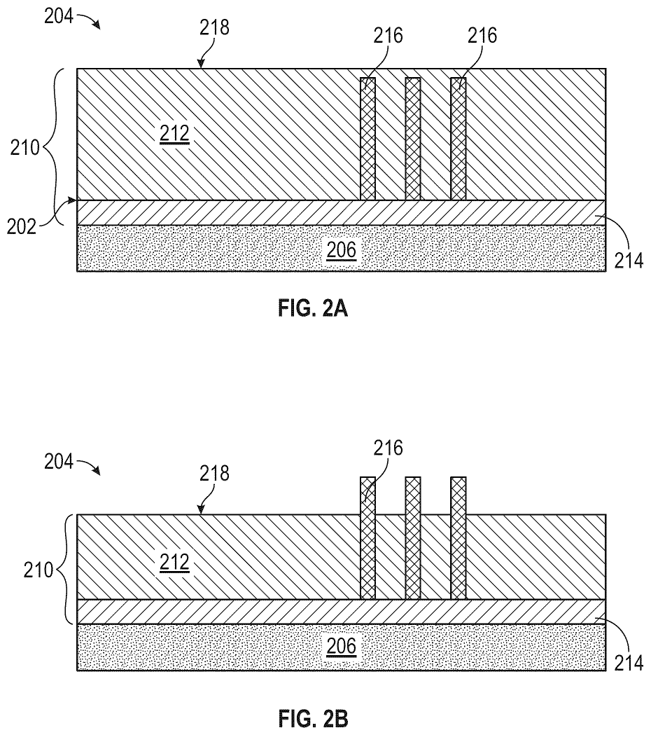

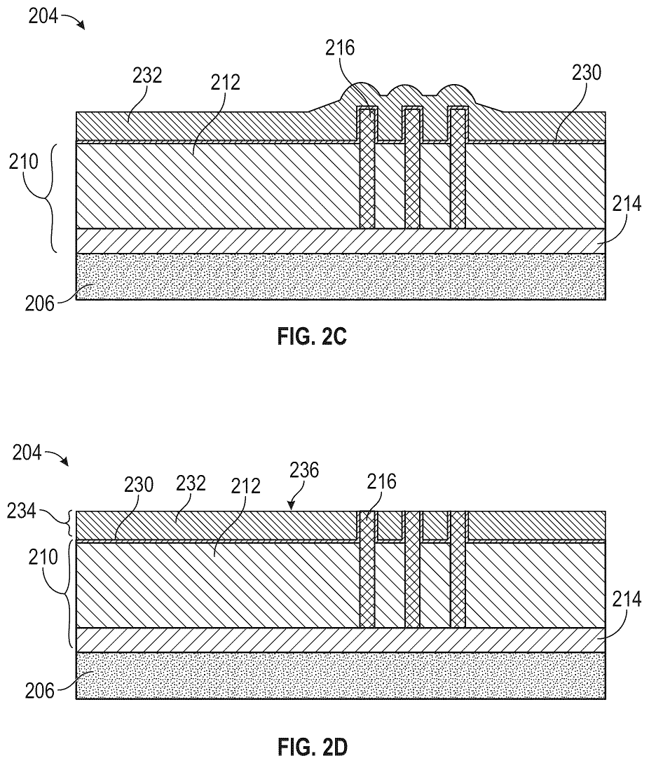

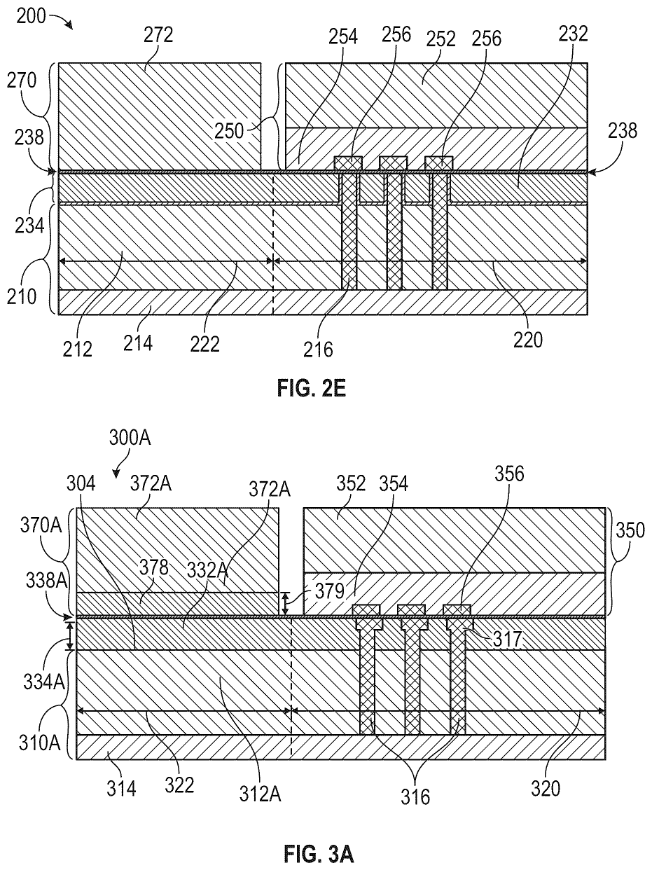

FIGS. 2A-2E depict a method of forming a conventional bonded structure 200 (depicted in FIG. 2E). FIG. 2A shows a bottom component 210 disposed onto a carrier 206. The bottom component 210 of FIG. 2A includes a front side 202 and a back side 204. The bottom component 210 can be an active device die, for example, a processor die or memory die. During use, the bottom component 210 can generate heat that, if not removed efficiently, can diminish the performance of the bottom component 210 or surrounding components. On the front side 202 of the bottom component 210 are active regions (e.g., semiconductor devices). Wiring layers 214, which can include redistribution layers and/or multilevel back-end-of-line (BEOL) layers are deposited and/or formed on the active side (e.g., front side 202). On the back side of the wiring layers 214 is a substrate 212, which has a top surface 218 at the back side 204. Active devices (e.g., transistors) are formed in the active regions of the front side 202 of the substrate 212. The substrate 212 can comprise a semiconductor material, such as silicon. Embedded within the substrate 212 are a plurality of through-substrate vias (TSVs) 216. The TSVs 216 are in electrical connection with the wiring layers 214 of the active region (e.g. semiconductor devices) of the substrate 212. The in-process TSVs 216 depicted in FIG. 2A are fully embedded within the substrate, such that the TSVs 216 are not exposed at the top surface 218 of the substrate 212 at this process stage.

The active region of the substrate 212 can comprise active devices (e.g., transistors) and/or circuitry, patterned or otherwise disposed therein. The wiring layers 214 can be formed over the active region of the substrate 212. The wiring layers 214 can comprise multiple layers. The wiring layers 214 can comprise a plurality of dielectric layers with embedded conductive features, such as conductive traces, vias and pads to form internal wiring or electrical routing. The exterior surface of the wiring layers 214 can be a bonding layer.

In some embodiments, the bottom component 210 can be directly bonded to the carrier 206. In some embodiments, the bottom component 210 can be adhered or otherwise mounted on the carrier.

FIG. 2B shows the structure of FIG. 2A after backside TSV reveal process. Backside via reveal can include multiple steps. A first step can include thinning the substrate 212 from the back side 204 of the bottom component 210 using a combination of coarse grinding and fine polishing processes including CMP to reach closer to the back side of TSVs 216 (typically within 1-10 um) without exposing them. A second step can include selective removal (e.g., a recess etch) of the substrate material (e.g., silicon) via wet or dry etch, until each TSV 216 protrudes from the substrate 212 at the back side 204 of the bottom component 210. In some TSV formation processes, the depth of TSVs formed at different locations on a wafer may vary (e.g. from 0.1 micron to 10 micron), due to nonuniformity in the depth of etching of the cavities into the substrate 212 that subsequently form TSVs. To expose and/or reveal each TSV 216, the selective backside removal of substrate material (e.g. silicon) can also have a large variation. In practice, the typical via protrusion can vary, for example, between 0.1 μm to 10 um. The substrate 212 can be etched. For example, the substrate 212 can be dry etched or wet etched. When dry etched, oxide (e.g. liner and/or barrier layer(s) optionally deposited during TSV fabrication process) can remain on TSV sidewalls.

FIG. 2C shows the structure of FIG. 2B after deposition of one or more dielectric layers 230 (e.g. liner, barrier, etc.) and a dielectric bonding layer 232 at the back side 204 of the bottom component 210 as the exposed ends of the vias are passivated. The one or more dielectric layers 230 can comprise one or more barrier dielectrics (for example, silicon nitride, silicon oxynitride, silicon carbonitride, silicon oxycarbonitride, nitrogen doped silicon carbide SiCₓN_{y}, or other compounds of the formula SiOₓN_{y}C_{z}). In some embodiments, the composition of the dielectric layer 230 may not be stochiometric throughout the thickness of the dielectric layer. For example, in the case of a SiCₓN_{y} barrier layer, the portion of the barrier layer contacting the back side 204 of the bottom component 210 may comprise a higher nitrogen concentration than the portion of the barrier layer contacting the dielectric bonding layer 232. The one or more dielectric layers 230 can assist with the backside planarization shown in FIG. 2D, to reduce or eliminate exposure or contamination of silicon from the TSVs 216. The dielectric bonding layer 232 can comprise a non-conductive material such as silicon oxide, silicon nitride, silicon oxynitride, silicon carbonitride, silicon oxycarbonitride, nitrogen doped silicon carbide SiCₓN_{y}, etc. The dielectric bonding layer 232 shown in FIG. 2C can be electrically non-conductive. The dielectric bonding layer 232 shown in FIG. 2C can also be poor thermal conductor (e.g., as compared to a semiconductor or metal). In some embodiments, the dielectric layer 232 may serve as the barrier layer and the bonding layer. For example, the composition of the dielectric bonding layer 232 may not be stochiometric throughout the thickness of the dielectric barrier layer. For example, in the case of silicon oxycarbonitride dielectric bonding layer 232, the portion of the bonding layer 232 contacting the back side 204 of the bottom component 210 may comprise a higher nitrogen or higher carbon concentration than the portion of the dielectric material disposed at the middle the dielectric layer 232. Similarly, in some embodiments, regardless of the nature of the dielectric material, the concentration of composition of its constituent atoms, for example, silicon, oxygen, carbon and nitrogen, etc. may vary within the thickness of the bonding dielectric layer 232.

FIG. 2D shows the structure of FIG. 2C after planarizing the back side 204 of the bottom component 210 to expose the TSVs 216. After planarization, the dielectric bonding layer 232 has a thickness 234 and a planarized top surface 236. The thickness 234 of the dielectric bonding layer 232 can depend, for example, on the process of via protrusion, which in turn can depend on the variation of the via depths when they are formed. The thickness 234 of the dielectric bonding layer 232 can, for example, be between approximately 0.5 microns and 3 microns, or between approximately 1 micron and 3 microns, or approximately 2 microns. The planarization can be done, for example, by grinding and/or polishing, for example, by chemical mechanical polishing (CMP). Optionally, after the planarization step shown in FIG. 2D, electrical contact pads (not shown) can be formed at the back side of the bottom component in electrical communication with the exposed portion of the TSVs. However, in the illustrated device, the ends of the TSVs 216 can serve as conductive contact features instead of forming separate discrete contact pads. In some embodiments, electrical contact pads (not shown) are formed at the back side of the bottom component, and the contact pads can be embedded in one or more dielectric layers deposited on top of dielectric bonding layer 232, such that the contact pads are in electrically communication with the TSVs. The thickness of the contact pads can be, for example, between 0.1 micron to 4 microns.

FIG. 2E shows a bonded structure 200, which comprises the bottom component 210 after being removed from the carrier 206, the dielectric bonding layer 232 disposed onto the bottom component 210, and two dies direct bonded to the dielectric bonding layer 232 at a bond interface 238. The two dies bonded to the dielectric bonding layer 232 at the bond interface 238 are a top die 250 and a heat dissipative die 270. The top die 250 is directly bonded (e.g., hybrid bonded) to the planarized top surface 236 of the dielectric bonding layer 232 disposed over a first region 220 of the bottom component 210. The first region 220 of the bottom component 210 includes the TSVs 216. The heat dissipative die 270 is directly bonded to the dielectric bonding layer 232 disposed over a second region 222 of the bottom component 210.

The top die 250 comprises conductive pads 256 that are directly bonded to the TSVs 216 of the bottom component 210. The top die 250 comprises a substrate 252, which can be similar to the substrate 212 of the bottom component 210. The top die 250 comprises active regions (not shown), on which wiring layers 254 are formed. Active devices (e.g., transistors) are formed in active regions of the substrate 252. The wiring layers 254 of the top die 250 can be similar to the wiring layers 214 of the bottom component 210. For example, the exterior surface of the wiring layers 254 can be a bonding layer. The conductive pads 256 of the top die 250 can be embedded into the bonding layer of the wiring layers 254 of the top die 250. The top die 250 can be an active die (e.g., a memory die, processor die, sensor die, etc.), which can generate heat when in use.

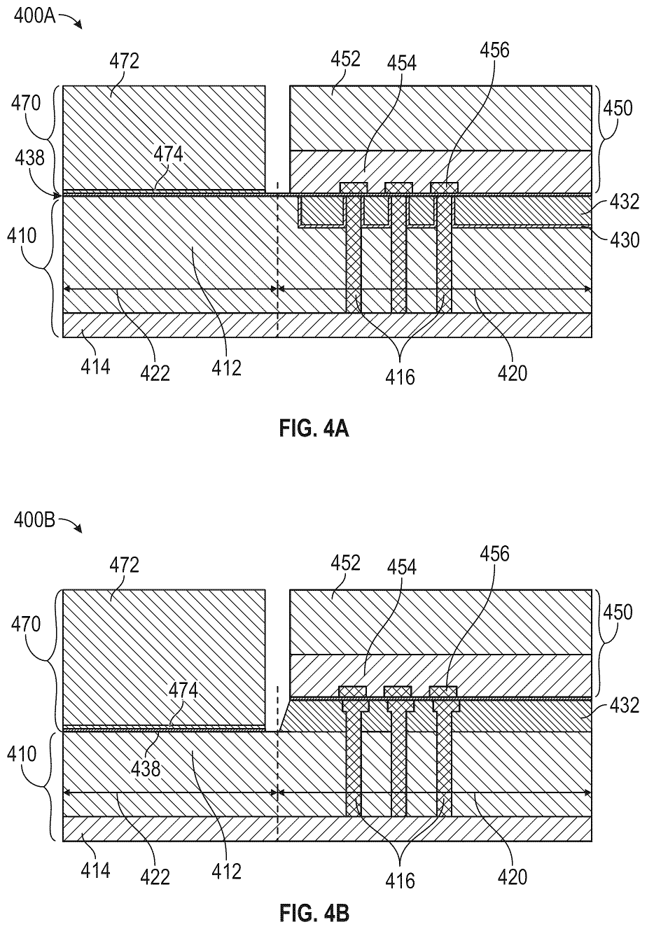

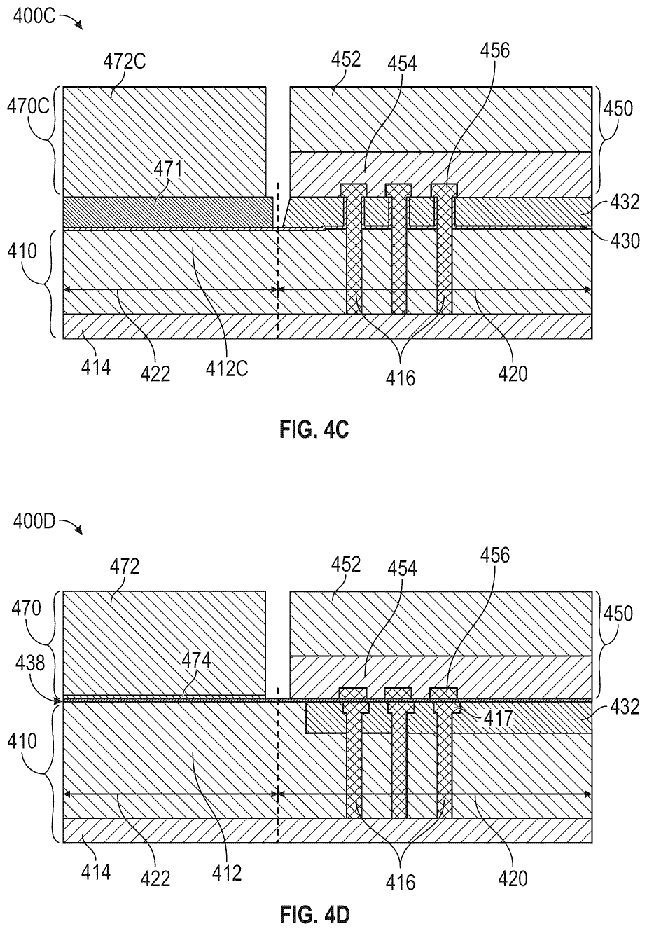

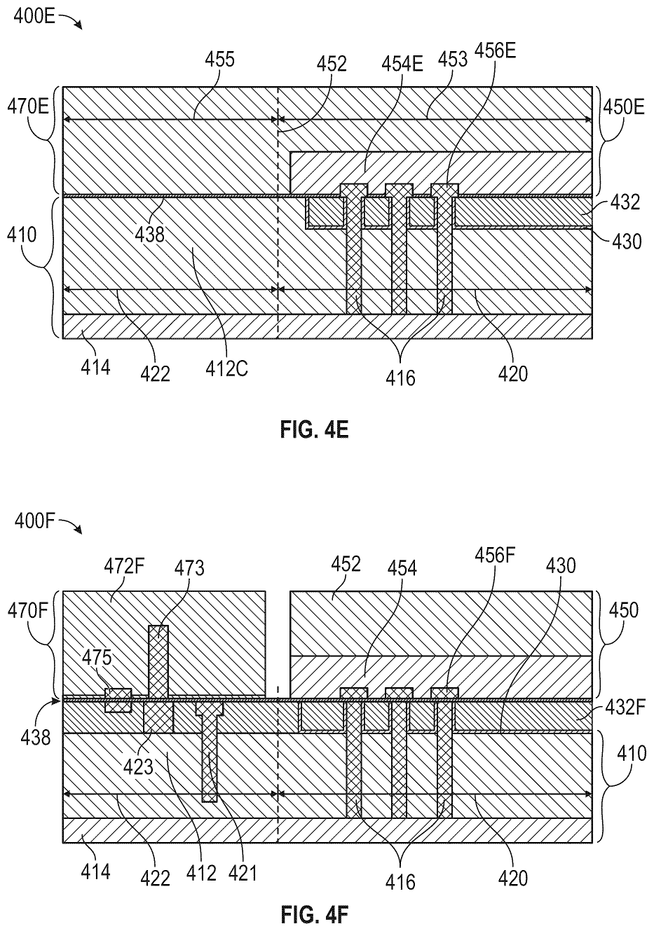

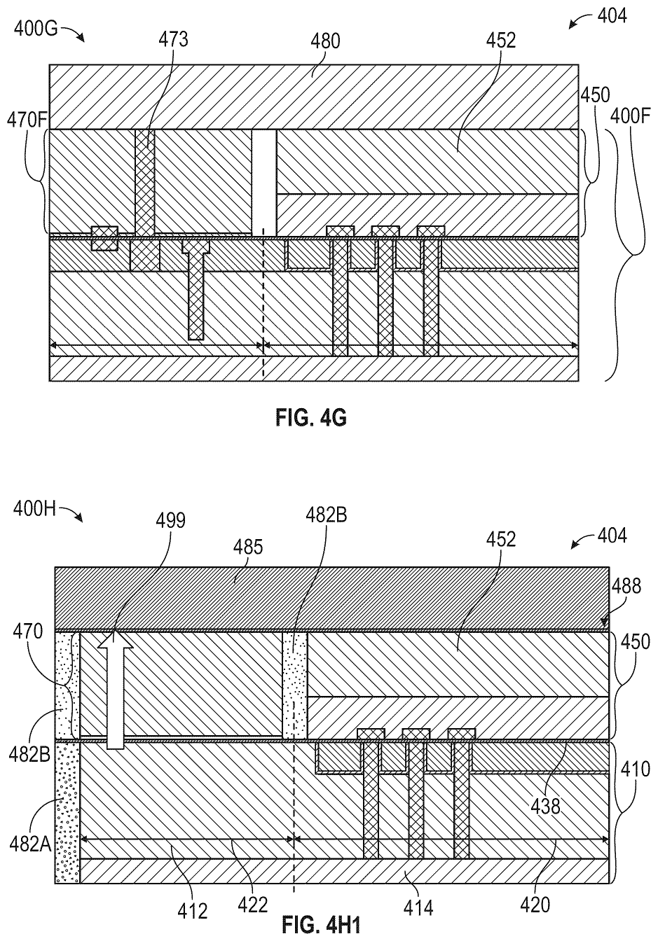

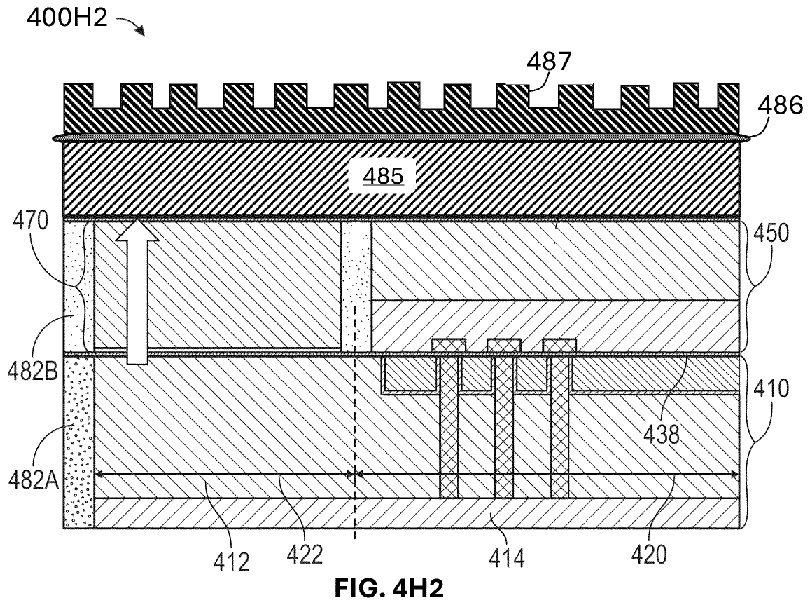

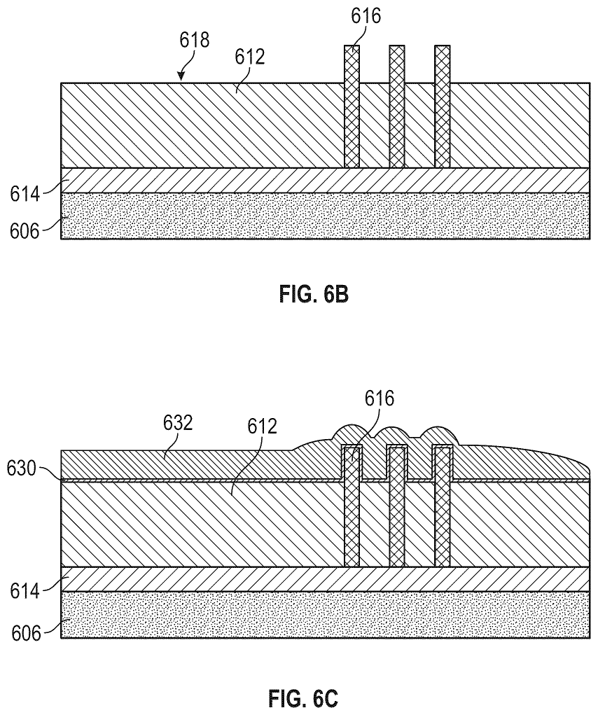

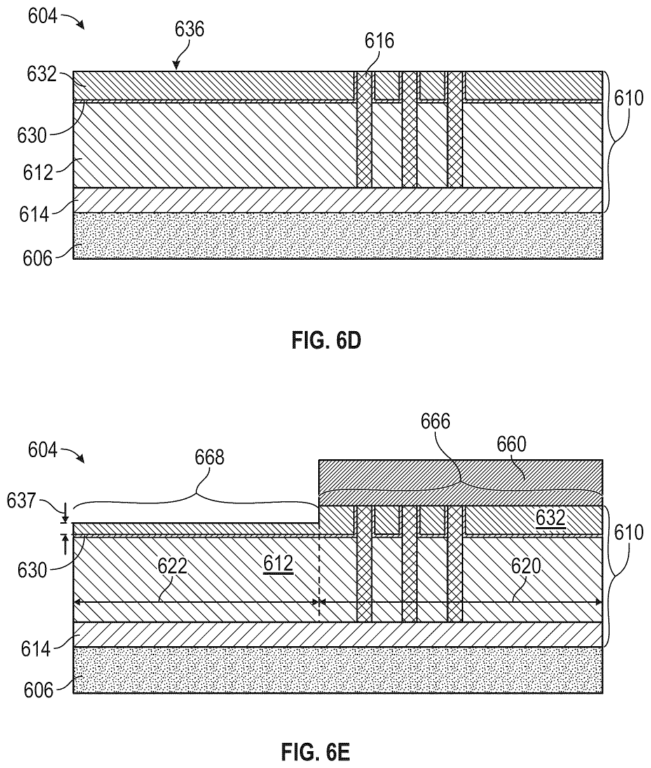

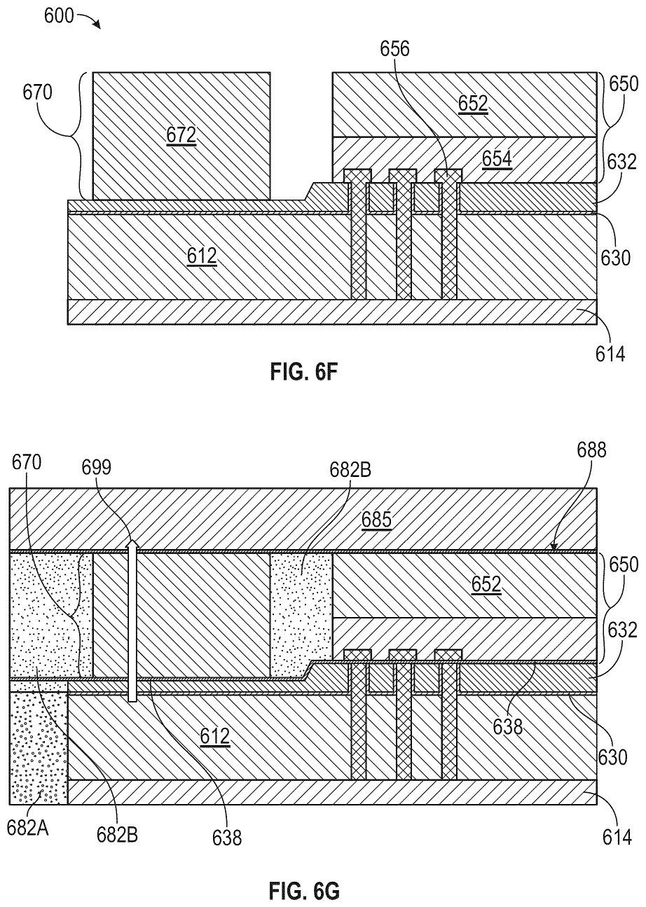

The heat dissipative die 270 shown in FIG. 2E comprises a substrate 272. The heat dissipative die 270 can be a dummy die without electronic components. The heat dissipative die 270 can be part of a thermal pathway configured to carry heat away from bottom component 210 and reduce the thermal exposure of the top die 250 from bottom component 210. The heat dissipative die 270 can, for example, comprise silicon, which can conduct heat away from an overheated die. The thermal pathway configured to carry heat away from a heat-generating component (e.g., bottom component 210) can include a heat spreader (not shown in FIG. 2E) bonded or attached to the top of at least one of the top die and the heat dissipative die. The heat spreader can extract heat away from the dies 250, 270. Nonlimiting examples of heat spreaders include the heat spreader 480 shown in FIG. 4G, the top carrier 485 shown in FIG. 4H1, the heat spreader 487 adhered to a top carrier 485 with a thermal interface material (TIM) shown in FIG. 4H2, and the top carrier 685 shown in FIG. 6G.

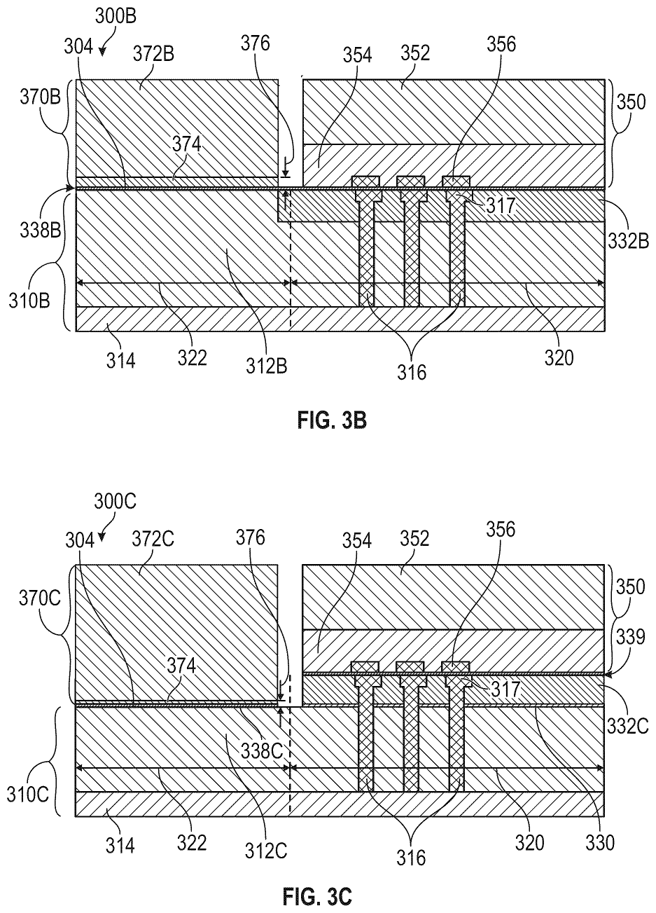

During use, the active region of the bottom component 210 and the active region of the top die 250 can generate heat. To prevent the bonded structure 200 from overheating, a thermal pathway is configured to carry away the generated heat. The thermal pathway can carry heat to a heat spreader (not shown), which can be attached to the back sides of top die 250 and dissipative die 270. The heat spreader can comprise, for example, a carrier die direct bonded to the back sides of top die 250 and dissipative die 270, which in turn can be attached to a heat spreader via thermal interface material. For example, heat generated by the bottom component 210 can be transferred to the heat dissipative die 270, which can carry heat away from the bonded structure 200. However, the thermally insulative dielectric bonding layer 232 obstructs the transfer of heat from the bottom component 210 to the heat dissipative die 270. For another example, heat generated by the top die 250 can be carried into the bottom component 210. Heat will be conducted from the top die 250 to the bottom component 210 more effectively through the TSVs 216, which are electrically and thermally conductive, than through the dielectric bonding layer 232, which is electrically and thermally insulative. However, a drawback in the thermal pathway of FIG. 2E is the deposited dielectric bonding layer 232 disposed over the second region 222 of the bottom component 210, which obstructs the transfer of heat into the heat dissipative die 270. For example, the deposited dielectric bonding layer 232 can comprise a deposited oxide layer with a thickness 234 of between approximately 0.5 microns and 3 microns, between approximately 1 microns and 5 microns, or between approximately 0.5 microns and 3 microns. The deposited oxide layer also has lower thermal conductivity than semiconductor material (e.g., silicon). The deposited dielectric bonding layer 232 can obstruct the efficient transfer of heat into the heat dissipative die 270 both because it has a comparatively low thermal conductivity and because it is comparatively thick (as compared, for example, to the native oxide 374 described with FIGS. 3B and 3C). The thermal pathway of the bonded structure 200 of FIG. 2E is obstructed by the thickness 234 of dielectric bonding layer 232 disposed over the second region 222 of the bottom component 210. Reducing or removing any such obstruction to the flow of heat would increase the efficiency with which heat can be dissipated or removed from heat-generating dies.

FIG. 3A depicts a conventional bonded structure 300A, which is similar in many respects to the bonded structure 200 shown in FIG. 2E. Like the bonded structure 200 of FIG. 2E, the bonded structure 300A comprises a bottom component 310A and a dielectric bonding layer 332A disposed over the bottom component 310A. Like the bonded structure 200 of FIG. 2E, the bonded structure 300A comprises a top die 350 bonded to the dielectric bonding layer 332A disposed over a first region 320 of the bottom component 310A. Like the bonded structure 200 of FIG. 2E, the bonded structure 300A comprises a heat dissipative die 370A bonded to the dielectric bonding layer 332A disposed over a second region 322 of the bottom component 310A. Dielectric bonding layer 332A has a thickness 334A, which can depend on, for example, the variety of TSV thicknesses and the thickness of conductive pads 317.

The bottom component 310A shown in FIG. 3A is similar to the bottom component 210 shown in FIG. 2E. The bottom component 310A comprises a substrate 312A, an active region of the substrate 312A where active devices are formed, and wiring layers 314 formed over the active region of the substrate 312A. The bottom component 310A comprises TSVs 316 embedded in the substrate 312A and in electrical communication with the wiring layers 314. The bottom component 310A also shows conductive pads 317, which are optional.

The top die 350 shown in FIG. 3A is the same as the top die 250 shown in FIG. 2E, with reference numerals incremented by 100.

The heat dissipative die 370A shown in FIG. 3A is similar to the heat dissipative die 270 shown in FIG. 2E. The heat dissipative die 370A shown in FIG. 3A has an additional deposited dielectric bonding layer 378. The deposited dielectric bonding layer 378 of heat dissipative die 370 has a thickness 379. The thickness 379 of the deposited dielectric bonding layer 378 can be, for example, between approximately 0.5 microns and 3.5 microns, or between approximately 1 micron and 3 microns.

The obstruction to the flow of heat into heat dissipative die 370A can be more rigorously examined. Heat conduction through a medium is directly proportional to the medium's thermal conductivity and inversely proportional to the thickness of the medium through which the heat is to be conducted. Obstructions to the conduction of heat are present, for example, when a material has a low thermal conductivity and/or is too thick. A material's conductivity changes with the surrounding temperature. A material's conductivity can also change based on how the material is processed. For example, the thermal conductivity of a pure, monocrystalline sample of material might be different than the same sample if grain boundaries were introduced. At least for these reasons, thermal conductivities are described herein with low precision (e.g., few significant figures). Copper is a good thermal conductor, with a conductivity of approximately 350-400 W/mK. Silicon is also a good thermal conductor, with a conductivity of approximately 200-250 W/mK. However, dielectric materials are thermal insulators, with very low thermal conductivity. For example, silicon dioxide has a thermal conductivity of approximately 1-2 W/mK or less, PECVD silicon nitride has a thermal conductivity of approximately 0.4-5 W/mK, and sputtered aluminum nitride has a thermal conductivity that can be as low as, for example, 40 W/mK. Thermal conductivity of such dielectric materials depend on, e.g., the type of the material (e.g. silicon oxide, TEOS (TetraEthylOrthoSilicate), silicon nitride, etc.), the dielectric deposition process (e.g. PECVD, LPCVD, high temperature oxide growth, etc.), and other parameters or restrictions (e.g. low temperature deposition, etc.).

In the embodiments of bonded structures described herein, one way thermal pathways can be improved is by reducing or eliminating the thickness of dielectric materials separating a dissipative feature (e.g., heat dissipative dies) from the source of the heat to be dissipated. In some embodiments, the thickness of dielectric materials separating a dissipative feature from the source of heat to be dissipated is between about 5 nm and 1 micron, or between about 10 nm and 500 nm, or between about 20 nm and 600 nm, or between about 100 nm and 500 nm, or between about 200 nm and 400 nm, or less than about 1 micron. In some embodiments, the deposited dielectric bonding layer 378 can include a dielectric material having a thermal conductivity higher than that of PECVD or sputtered or evaporated silicon oxide. In one embodiment the thermal conductivity of the deposited dielectric bonding layer 378 is higher 2.5 W/mK.

FIGS. 3B and 3C depict bonded structures 300B and 300C, respectively. The bonded structures 300B and 300C both have thermal pathways that are more effective than those of bonded structures 300A shown in FIG. 3A of bonded structure 200 shown in FIG. 2E.

FIGS. 3B and 3C share some general features with FIG. 3A. All components that have reference numerals without letters (for example, top die 350) are the same between FIGS. 3A-3C. In addition, the general configuration of the bonded structures 300A, 300B, 300C are similar. Bonded structures 300A, 300B, 300C all have a bottom component 310A, 310B, 310C with a top die 350 bonded over a first region 320 of the bottom component. Bonded structures 300A, 300B, 300C have a heat dissipative die 370A, 370B, 370C bonded over a second region 322 of the bottom component 310A, 310B, 310C. Additionally, the back side 304 of the heat dissipative dies 370A, 370B, 370C can be substantially coplanar with the back side 304 of the top dies 350. While such coplanarity at the back side 304 is optional, the coplanarity at the back side 304 of the heat dissipative dies and top dies facilitates the addition of subsequent bonding layers. The top die 350 and the heat dissipative die 370B, 370C can be encapsulated or reconstituted (not shown) in some embodiments. Additionally, a top carrier (not shown) can be bonded to the back side 304 of the bonded structure 300B, 300C (e.g. after polishing the backside of the encapsulated or reconstituted dies). The top carrier (not shown) can be a heat spreader.

Bonded structures 300B and 300C include various features that are absent from bonded structure 300A. Unlike in FIG. 3A, the deposited dielectric bonding layers 332B and 332C are only disposed over the first region 320 of the bottom components 310B, 310C. Accordingly, in the embodiments of FIGS. 3B-3C, heat dissipative dies 370B and 370C are directly bonded to the substrate 312B, 312C of the bottom component 310B, 310C. Dissipative dies 370B and 370C can be uniformly directly bonded to the substrate 312B, such that only nonconductive regions are bonded without adhesive (e.g., there are no conductive direct bonds). As shown in FIGS. 3B and 3C, TSVs 316 are embedded in the first region 320 of the bottom components 310B, 310C. In some embodiments, the dielectric bonding layers 332B and 332C can extend laterally beyond the plurality of TSVs 316 by more than one micron. For example, the dielectric bonding layers 332B and 332C can extend laterally beyond the plurality of TSVs 316 by between about 5 microns and 200 microns, between about 10 microns and 100 microns, between about 25 microns and 75 microns, more than about 5 microns, more than about 10 microns, more than about 50 microns, or more than about 100 microns.

Heat dissipative dies discussed throughout this disclosure (e.g., heat dissipative dies 370B and 370C) can be dummy dies. Dummy dies, as discussed herein, have less active circuitry than do nearby active dies (e.g., the bottom component 310B, 310C or top die 350). In some embodiments, heat dissipative dies 370B, 370C have fewer than 5% of the transistors of the active dies (e.g., the bottom component 310B, 310C or top die 350). For example, the heat dissipative dies 370B, 370C can have fewer than 1%, in a range of 0.1% to 5%, in a range of 0.5% to 3%, or in a range of 1%-2% of the transistors of the active dies (e.g., the bottom component 310B, 310C or top die 350). In some embodiments, only a small percentage of the surface area of the heat dissipative die comprises active circuitry. For example, the percentage of surface area of the heat dissipative die comprising active circuitry can be less than 5%, in a range of 0.1% to 5%, in a range of 0.1% to 3%, in a range of 0.5% to 2%, or in a range of 0.5% to 1%. In some embodiments, heat dissipative dies can comprise passive electronics. In some embodiments, heat dissipative dies can comprise metal wiring. In some embodiments, heat dissipative dies may be devoid of transistors (e.g., have no active devices or circuitry).

Additionally, whereas the heat dissipative die 370A of FIG. 3A has a deposited dielectric bonding layer 378, the heat dissipative dies 370B, 370C of FIGS. 3B and 3C can have no deposited dielectric layer (e.g., no deposited silicon oxide layer). In some embodiments, the heat dissipative dies 370B, 370C of FIGS. 3B and 3C have no deposited bonding dielectric (e.g. silicon oxide). In some embodiments, the heat dissipative dies 370B, 370C of FIGS. 3B and 3C have less than 100 nm of deposited dielectric (e.g. silicon oxide, silicon nitride, etc.). In some embodiments, the heat dissipative dies 370B, 370C of FIGS. 3B and 3C have less than 10 nm of deposited dielectric (e.g. silicon oxide, silicon nitride, etc.). In some embodiments, the heat dissipative dies 370B, 370C of FIGS. 3B and 3C have only native oxide 374. The native oxide 374 is not deposited onto the substrate 372B, 372C of the heat dissipative die 370B, 370C. The native oxide 374 is a non-deposited dielectric layer. The native oxide 374 can spontaneously form on an exposed surface of silicon. The thickness 376 of the native oxide 374 can be orders of magnitude smaller than a corresponding thickness of the wiring layers 354 of the top die 350. The thickness 376 of the native oxide 374 can be orders of magnitude smaller than the thickness of the dielectric bonding layer 332B, 332C. The thickness 376 of the native oxide 374 can be between about 0.01 nm and 4 nm, between 0.1 nm and 3 nm, less than 2 nm, less than 10 nm or less than 20 nm. Because the native oxide 374 is so thin, especially compared to the various deposited insulative layers of the bonded structure, the native oxide 374 does not materially impede the conduction of heat away from overheated dies. As stated above, the native oxide 374 is substantially thinner than the deposited dielectric bonding layer 378 shown in FIG. 3A. Optionally, the heat dissipative dies 370B, 370C can be designed or processed to have no native oxide layer. With or without a native oxide 374, the heat dissipative dies 370B and 370C can be processed to have a bonding surface capable of being directly bonded to the bottom component 310B, 310C without an intervening adhesive. Unlike in the bonded structure 300A of FIG. 3A, bonded structures 300B and 300C have a bond interface 338B, 338C without significant dielectric material between the bottom component 310B, 310C and the dissipative substrate 372B, 372C of the heat dissipative die 370B, 370C.

Just like the heat dissipative die 370B, 370C can have a thin layer of non-deposited (e.g., native) oxide 374, a thin surface layer of non-deposited native oxide can also be part of the semiconductor region of the bond interface 338B, 338C. For example, a native oxide (not shown) can be on the surface of the second region 322 of the bottom component 310B, 310C. In some embodiments, the surface of the second region 322 of the bottom component 310B, 310C can have less than 100 nm of deposited dielectric (e.g. silicon oxide, silicon nitride, etc.).

The bonded structures 300B and 300C both have thermal pathways that are more effective than those of bonded structures 300A shown in FIG. 3A or bonded structure 200 shown in FIG. 2E. Beneficially, bonded structures 300B and 300C have minimal (e.g. <100 nm thick) or no deposited dielectric bonding layer 332B or 332C deposited over the second region 322 (which is a semiconductor region) of the bottom component 310B, 310C. And beneficially, the heat dissipative dies 370B and 370C have minimal (e.g. <100 nm thick) or no deposited dielectric bonding layer like the deposited dielectric bonding layer 378 of the heat dissipative die 370A shown in FIG. 3A.

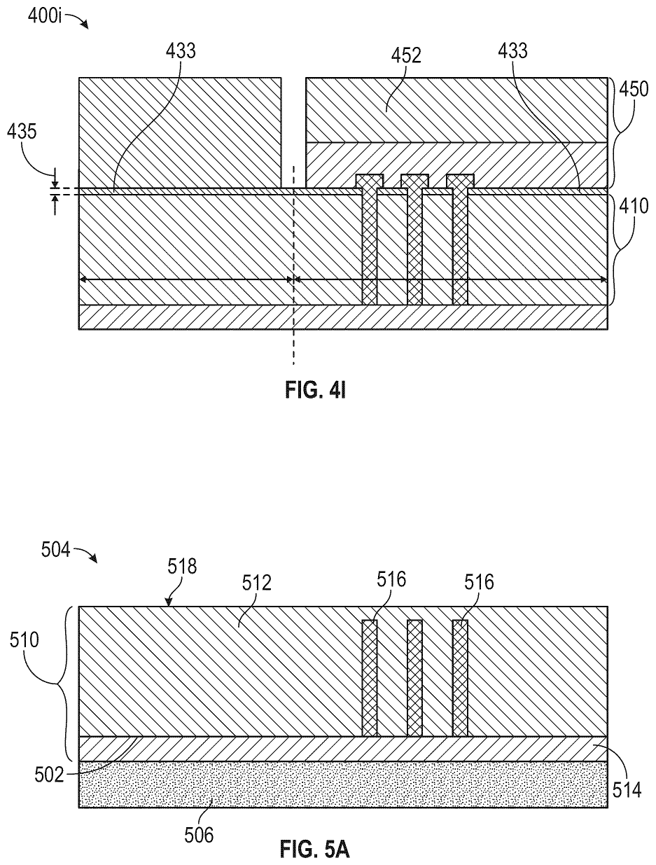

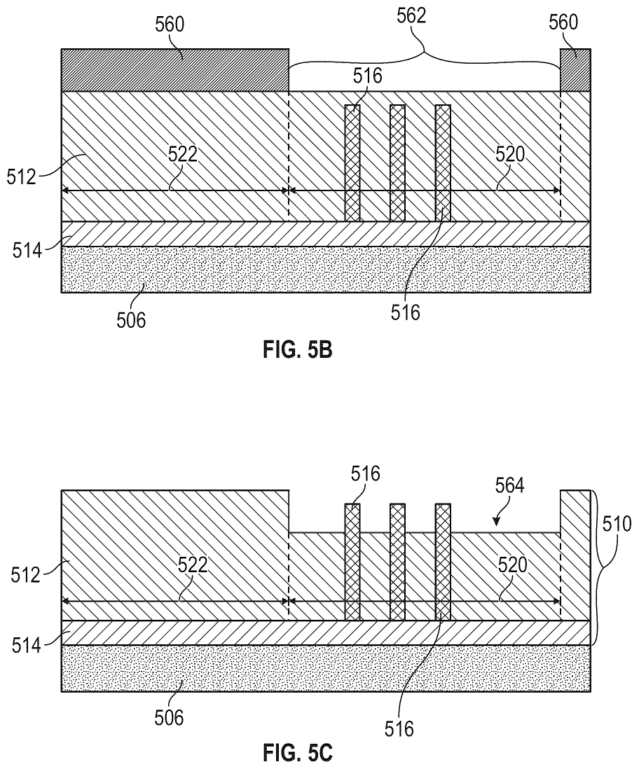

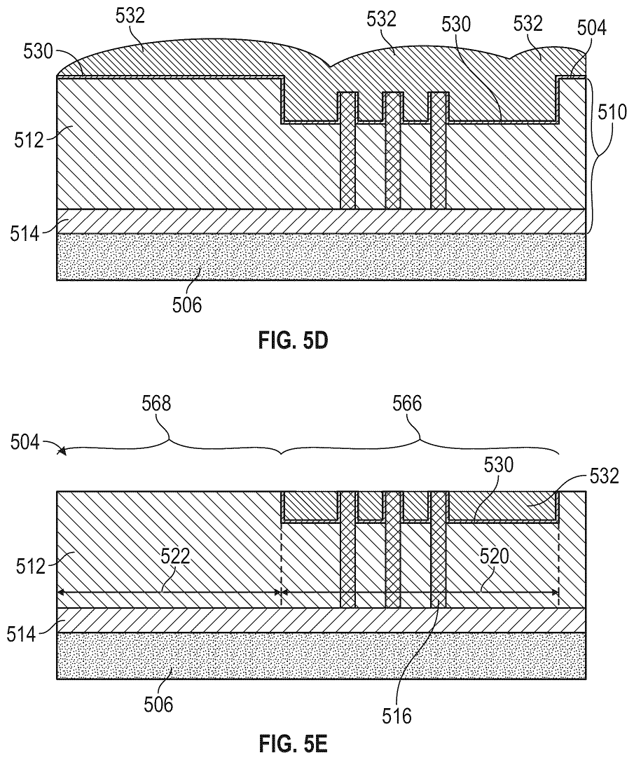

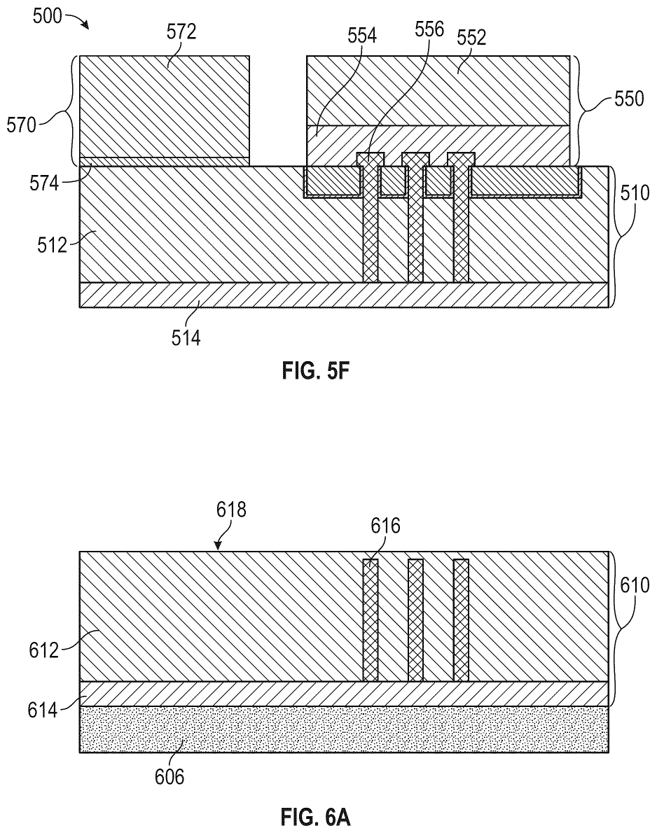

The bonded structure 300B of FIG. 3B is different from the bonded structure 300C of FIG. 3C in various aspects. In the bonded structure 300B of FIG. 3B, the first region 320 of the substrate 312B is recessed, and dielectric bonding layer 332B is deposited in the recess. As a result, the bond interface 338B between the bottom component 310B and the top die 350 is substantially coplanar with the bond interface between the bottom component 310B and the heat dissipative die 370B. In the bonded structure 300C of FIG. 3C, however, the bond interface 339 between the bottom component 310C and the top die 350 is above—not substantially coplanar with—the bond interface 338C between the bottom component 310C and the heat dissipative die 370C. The method of forming a bonded structure like the bonded structure 300B of FIG. 3B is shown in FIGS. 5A-5F. The method of forming a bonded structure like the bonded structure 300C of FIG. 3C is shown in FIGS. 6A-6F.

In embodiments discussed herein, bottom components (e.g., 310, 410, 510, 610, etc.) and top dies (e.g., 350, 450, 550, 650, etc.) can comprise any suitable types of active dies (e.g., processor dies, memory dies, sensor dies, MEMS dies, power dies, etc.). In illustrated embodiments, top dies (e.g., 350) comprise a memory die or memory unit, and bottom components (e.g., 310B, 310C) comprise a processor die. When powered on, processor dies can generate substantially more heat than memory dies. In illustrated embodiments, bottom components (e.g., 310B, 310C) can generate substantially more heat than top dies (e.g., 350). For this reason, beneficially, an efficient thermal pathway can be configured, using a heat dissipative die (e.g., 370B, 370C) to remove heat from the bottom components (e.g., 310B, 310C). In some embodiments, the bottom component (e.g., 310B, 310C) and top die (e.g., 350) can both be processor dies that generate substantial heat. In such embodiments, the top die (e.g., 350) can be directly attached to a heat spreader or carrier on the back side, while at least some of the heat generated by the bottom component (e.g., 310B, 310C) can be removed through the dissipative die (e.g., 370B, 370C).

FIGS. 4A-4I depict various embodiments of bonded structures with various configurations of efficient thermal pathways between a bottom component and a dissipative feature of a top layer of bonded dies. For example, the efficient thermal pathways are between a second region 422 of the bottom components and a dissipative feature bonded thereover. FIGS. 4A-4I are nonlimiting examples of thermal pathway configurations, illustrating a variety of available configurations.

FIG. 4A depicts a bonded structure 400A similar to the bonded structure 300B of FIG. 3B. However, bonded structure 400A of FIG. 4A differs from bonded structure 300B of FIG. 3B in how the conductive features in the first region 420 of the bottom component 410 are bonded to the conductive pads 456 of the top die 450. In bonded structure 300B of FIG. 3B, conductive pads 317 are formed contacting the exposed ends of TSVs 316 (directly or using one or more wiring or RDL). The conductive bond at bond interface 338B is a pad-to-pad conductive direct bond in which pads 317 serve as conductive contact features: conductive pads 317 of the bottom component 310 are directly bonded to the pads 356 of the top die 350. In bonded structure 400A of FIG. 4A, however, the conductive bond at interface 438 is a TSV-to-pad conductive direct bond in which ends of the TSVs 416 serve as conductive contact features: TSVs 416 of the bottom component 410 are directly bonded to the pads 456 of the top die 450. The TSVs 416 of bonded structure 400A of FIG. 4A can also optionally have a liner 430 (e.g., a dielectric barrier), similar to dielectric layer 230 of bonded structure 200 of FIG. 2E and/or a barrier layer (not shown). The barrier layer can comprise a conductive barrier of TSVs 316.

FIG. 4B depicts a bonded structure 400B similar to the bonded structure 300C of FIG. 3C.

FIG. 4C depicts a bonded structure 400C similar to the bonded structure 400A of FIG. 4A. However, bonded structure 400C of FIG. 4C differs from bonded structure 400A of FIG. 4A in how the heat dissipative die 470 is bonded to the bottom component 410. In bonded structure 400A of FIG. 4A, the heat dissipative die 470 is directly bonded to the substrate 412 of the bottom component 410 without an intervening adhesive or bonding layer. However, in bonded structure 400C of FIG. 4C, a metallic bonding layer 471, such as solder or other thermally conductive adhesive, intervenes between the substrate 412C of the bottom component 410 and the substrate 472C of heat dissipative die 470C. In this embodiment, heat dissipative die 470C can be processed (e.g. metallized) so as to allow joining via solder, etc. to the bottom component 410. The metallic bonding layer 471 enhances the flow of heat because the metallic bonding layer 471 comprises a thermally conductive material.

FIG. 4D depicts a bonded structure 400D similar to the bonded structure 300B of FIG. 3B.

FIG. 4E depicts a bonded structure 400E similar to the bonded structure 400A of FIG. 4A. However, bonded structure 400E differs from bonded structure 400A in that, in the bonded structure 400E the top die 450E can comprise an active portion (with active circuitry) and a heat dissipative or dummy portion to transfer heat to the outside environs (in a manner similar to the heat dissipative dies). In the bonded structure 400A of FIG. 4A, the top die 450 is separate and distinct from the heat dissipative die 470. However, in the bonded structure 400E of FIG. 4E, the substrate 452 of the top die 450E has an active portion 453 and a dissipative portion 455. Active devices (e.g., transistors) are provided in the active portion 453 of the substrate 452. The wiring layers 454E and conductive pads 456E embedded therein are formed on the active portion 453 of the substrate 452 of the top die 450E. The top die 450E is directly bonded to the bottom component 410 such that the active portion 453 of the top die 450E is bonded to the first region 420 of the bottom component 410, and such that the dissipative portion 455 of the top die 450E is bonded to the second region 422 of the bottom component 410. In essence, the active portion 453 of the top die 450E in FIG. 4E corresponds to the top die 450 in FIG. 4A, and the dissipative portion 455 of the top die 450E in FIG. 4E corresponds to the heat dissipative die 470 in FIG. 4A. In some embodiments, the top die 450E can be formed by etching or otherwise forming a cavity within the substrate 452, into which the bonding layer can be deposited, for example, over active circuitry. Reducing the number of number bonded dies—from 3 dies bonded in other embodiments to 2 dies bonded in the embodiment shown in FIG. 4E—can improve manufacturing efficiency, saving processing time and/or cost.

FIG. 4F depicts a bonded structure 400F different from the bonded structure 200 of FIG. 2E. The bonded structure 400F has thermally conductive components to overcome the thermal obstruction posed by the dielectric bonding layer 232 disposed over the second region 222 of the bottom component 210 in FIG. 2E. Unlike bonded structures 400A-400E in which the dielectric bonding layer 432 is not disposed over the second region 422 of the substrate 412 of the bottom component 410, bonded structure 400F has a dielectric bonding layer 432 disposed across the first and second regions 420, 422 of the bottom component 410. However, to overcome the obstruction to the flow of heat presented by the dielectric bonding layer 432, a plurality of thermally conductive vias 421 and/or thermally conductive pads 423 are embedded into the second region 422 of the bottom component 410 and fully through the dielectric bonding layer 432. These thermally conductive vias and pads 421, 423 (e.g. thermal vias and thermal pads) effectively transfer heat across the dielectric bonding layer 432 to the heat dissipative die 470F. The thermally conductive vias and pads 421, 423 need not be in electrical connection with the active region or with the wiring layers 414 of the bottom component 410. Whereas the TSVs 416 embedded in the first region 420 of the substrate 412 of the bottom component 410 are in electrical connection with the active region and with the wiring layers 414 of the bottom component 410, the thermally conductive vias and pads 421, 423 serve to transfer heat between the bottom component 410 and the heat dissipative die 470F, not electrical signal.

The heat dissipative die 470E of FIG. 4F is also different from the heat dissipative die 470 of FIGS. 2E and 4A. The heat dissipative die 470E of FIG. 4F can have one or more conductive vias 473 and/or at least one conductive pad 475. The thermally conductive via 473 and pad 475 are configured to be directly bonded to the thermally conductive vias and pads 421, 423 of the bottom component 410. However, the at least one conductive via 473 and/or at least one conductive pad 475 embedded in the heat dissipative die 470F is optional. In some embodiments, thermally conductive via 473 is partially embedded into the substrate 472F of the heat dissipative die 470F. In some other embodiments, thermally conductive via 473 is through-via and can be exposed at the backside of the substrate 472F of the heat dissipative die 470F. The bonded structure 400F would also have an efficient thermal pathway if the heat dissipative die had no embedded conductive features.

FIG. 4G depicts a bonded structure 400G similar to the bonded structure 400F of FIG. 4F, with a heat spreader 480 attached or bonded to the back side 404 of the top die 450 and to the back side 404 of the heat dissipative die 470F. FIG. 4G also shows a conductive via 473 (e.g. through via) of the heat dissipative die 470F in contact with the heat spreader 480. Such contact is optional. In bonded structure 400G, heat from the bottom component 410 is transferred to heat dissipative die 470F (as described with FIG. 4F above), then to the heat spreader 480, which can carry away the heat to the outside environs.

The heat spreader can transfer heat from the bonded dies (e.g., 410, 450, and 470F) to the outside environs. The heat spreader 480 can comprise any suitable material or configuration to achieve this purpose. In some embodiments, the heat spreader 480 can comprise a thermally conductive material or component, such as copper, aluminum, or nickel. In some embodiments, the heat spreader 480 can comprise a semiconductor material that conducts heat, such as silicon.

In some embodiments, the heat spreader 480 can be a cavity die with fluid coolant in it. In some embodiments, the heat spreader 480 can comprise coolant pathways such that a fluid coolant can be pumped through the coolant pathways. In some embodiments, the heat spreader (e.g. copper or aluminum heat spreader) can be attached using thermal interface material. In some embodiments, the heat spreader (e.g. carrier or silicon) is directly bonded to the back side 404 of the top die 450 and to the back side 404 of the heat dissipative die 470F. In some embodiments, the heat spreader (e.g. carrier or silicon) is directly bonded to a bonding layer formed or deposited at the back side 404 of the top die 450 and to the back side 404 of the heat dissipative die 470F. In some embodiments, the heat spreader 480 includes a semiconductor device (e.g., bonded dies 410, 450, 470F) and a cold plate attached to the semiconductor device. Typically, the cold plate is formed with recessed surfaces that define one or more fluid cavities (e.g., coolant chamber volume(s) or coolant channel(s)) between the cold plate and the semiconductor device. In embodiments where the cold plate is formed with plural fluid cavities, each fluid cavity may be defined by cavity dividers and/or sidewalls of the cold plate. For example, cavity dividers may be spaced apart from each other and extend laterally between opposing cold plate sidewalls (e.g., in one direction between a first pair of opposing cold plate sidewalls, or in two directions between orthogonal pairs of opposing cold plate sidewalls). The cavity dividers and the cold plate sidewalls may collectively define adjacent fluid cavities therebetween. The cold plate may comprise a polymer material. The cold plate may be attached to the semiconductor device by use of a compliant adhesive layer or by direct bonding or hybrid bonding. For example, the cold plate may include material layers and/or metal features which facilitate direct bonding or hybrid bonding with the semiconductor device. Beneficially, the backside of the semiconductor device is directly exposed to coolant fluids flowing through the integrated cooling assembly, thus providing for direct heat transfer therebetween. Unless otherwise noted, the integrated cooling assemblies described herein may be used with any desired fluid, e.g., liquid, gas, and/or vapor-phase coolants, such as water, glycol etc. In some embodiments, the coolant fluid(s) may contain additives to enhance the conductivity of the coolant fluid(s) within the integrated cooling assemblies. The additives may comprise, for example, nano-particles of carbon nanotubes, nano-particles of graphene, and/or nano-particles of metal oxides. The concentration of these nano-particles may be less than 1%, less than 0.2%, or less than 0.05%. The coolant fluids may also contain small amount of glycol or glycols (e.g. propylene glycol, ethylene glycol, etc.) to reduce frictional shear stress and drag coefficient in the coolant fluid(s) within the integrated cooling assembly. In embodiments having plural coolant chamber volumes and/or plural coolant channels, each coolant chamber volume and/or coolant channel may be connected between a separate inlet opening and a separate outlet opening. In such embodiments, coolant fluid may be directed to the separate inlet openings and from the separate outlet openings using a manifold disposed above the openings in a mutually orthogonal direction (e.g., a vertical direction).

FIG. 4H1 depicts a bonded structure 400H similar to the bonded structure 400A of FIG. 4A, with various additional features. Laterally adjacent to the bottom component 410 is encapsulant 482A. The encapsulant 482A builds up the area laterally adjacent to the bottom component 410 up to the level of the first bond interface 438.

In some embodiments, the encapsulant (e.g., 482A) can comprise a reconstitution material. In some embodiments, the reconstitution material comprises a reconstitution dielectric. In some embodiments, the reconstitution dielectric comprises an inorganic dielectric (e.g. silicon oxide, silicon nitride, silicon oxynitride, silicon carbonitride, silicon oxycarbonitride, etc.). In some embodiments, the reconstitution dielectric comprises an organic dielectric, such as a molding compound, resin or epoxy. In some embodiments, the encapsulant comprises one material, such as silicon oxide, a molding compound, or the like. In some embodiments, the encapsulant comprises a plurality of materials. For example, a first layer can comprise a conformal inorganic dielectric (e.g., silicon nitride) over each die layer. In some embodiments, a second layer of encapsulant can comprise a filler to fill the gaps. In some embodiments, the filler can comprise a filler inorganic dielectric, such as silicon oxide. In some embodiments, the filler can comprise a filler organic dielectric, such as epoxy or the like.

Between the top die 450 and the heat dissipative die 470 is encapsulant 482B. In some embodiments, encapsulant 482B comprises the same or different material or materials as encapsulant 482A. In some embodiments, encapsulant 482B comprises different material as encapsulant 482A. The encapsulant 482B can also build up the area laterally adjacent to the heat dissipative die 470 up to the level of a second bond interface 488. It will be understood that encapsulant can also be disposed laterally adjacent to the top die 450. In some embodiments, the encapsulant comprises one material or a plurality of materials. For example, a first layer can comprise a conformal inorganic dielectric (e.g., silicon nitride) over each die layer. (including the top die, thermal die and bottom dies). In some embodiments, a second layer of encapsulant can comprise a filler to fill gaps. In some embodiments, the filler can comprise a filler inorganic dielectric, such as silicon oxide. In some embodiments, the filler can comprise a filler organic dielectric, such as epoxy or the like. Bonded structure 400H also shows a top carrier 485 directly bonded to the back side 404 of the top die 450, to the back side 404 of the heat dissipative die 470F, and to the back side of encapsulant 482B. The top carrier 485 can be similar to the heat spreader 480 shown in FIG. 4G and described above. In some embodiments, the top carrier 485 can be laterally wider, in one or both dimensions, than the combined width of the heat dissipative die 470, the top die 450, and the encapsulant 482B. In some embodiments, the top carrier 485 can have the same width, in one or both dimensions, as the combined width of the heat dissipative die 470, the top die 450, and the encapsulant 482B. In some embodiments, the top carrier 485 can be less wide, in one or both dimensions, than the combined width of the heat dissipative die 470, the top die 450, and the encapsulant 482B. In some embodiments, the top carrier 485 can be directly bonded (e.g., uniformly directly bonded) to underlying layers. In some embodiments, the top carrier 485 can be adhered to the underlying layers, for example, with a thermal interface material (i.e., TIM). In some embodiments, after encapsulant is added, the bonded structure can be singulated into various multi-layer dies.

Bonded structure 400H is annotated with the direct thermal pathway 499, showing the unobstructed dissipation of heat from the substrate 412 of the bottom component 410 and adjacent encapsulant 482A, vertically up through the heat dissipative die 470 and adjacent encapsulant 482B, to the top carrier 485. Beneficially, minimal or no deposited dielectric or other deposited insulating material obstructs the direct thermal pathway 499.

FIG. 4H2 depicts a bonded structure 400H2 similar to the bonded structure 400H of FIG. 4H1 with a heat spreader 487 (e.g., copper heat spreader or heat pipe) adhered to the top carrier 485, for example, with a thermal interface material (i.e., TIM) 486. In some other embodiments, another carrier (e.g. liquid colling cavity die) is direct bonded to the top carrier 485. In some embodiments, the top carrier 485 can be direct bonded to the underlying layers including surfaces of die 470 and 450 along with reconstituted dielectric or encapsulation 482B. In some other embodiments, the top carrier 485 can be direct bonded to the underlying bonding layer deposited on the surfaces of die 470 and 450 along with reconstituted dielectric or encapsulation 482B. In some other embodiments, another carrier (e.g. liquid cooling cavity die) is direct bonded to the top carrier 485.

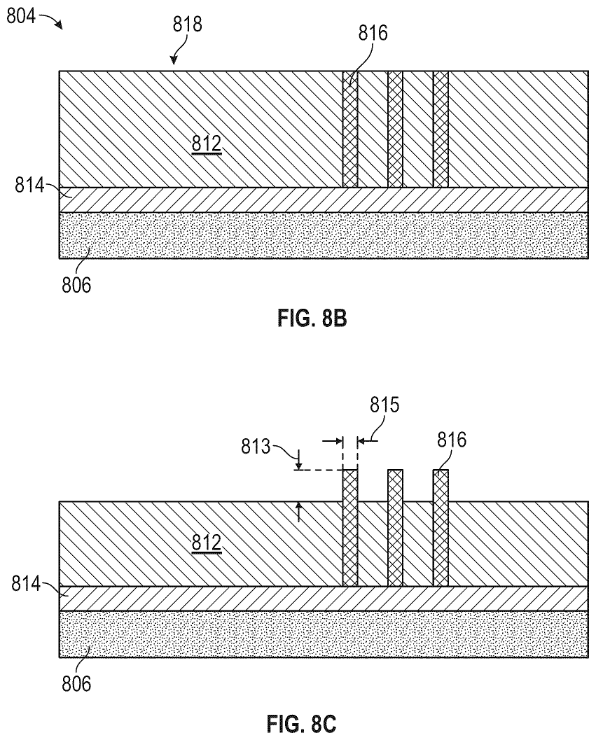

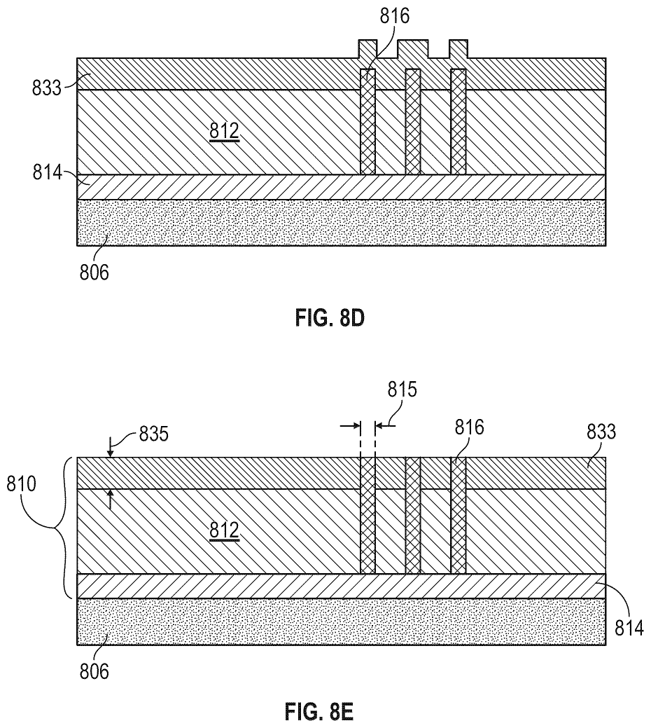

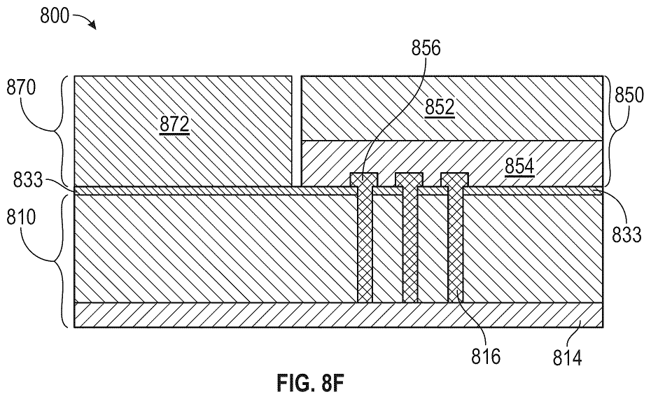

FIG. 4I depicts a bonded structure 400I different from the bonded structure 200 of FIG. 2E. Whereas the dielectric bonding layer 232 of the bonded structure 200 of FIG. 2E has thickness 234 greater than one micron, the ultrathin dielectric bonding layer 433 of bonded structure 400I of FIG. 4I has a thickness 435 of less than about 500 nm. The thickness 435 of the ultrathin dielectric bonding layer 433 can be less than about 500 nm, less than about 400 nm, less than about 200 nm, less than about 100 nm, less than about 50 nm, or less than about 40 nm. The ultrathin dielectric bonding layer 433 is thin enough to still efficiently allow for the dissipation of heat across it. The method of forming a bonded structure like the bonded structure 400I of FIG. 4I is shown in FIGS. 8A-8F.

FIGS. 4A-4I illustrate a nonlimiting variety of thermal pathway configurations. For example, the conductive pads 454 of the top die 450 can be directly bonded to TSVs 416 (as shown in FIG. 4A) or to conductive pads 417 (as shown in FIG. 4D). The bond interface between the bottom component and the top die can be substantially coplanar with the bond interface between the bottom component and the heat dissipative die (as shown in FIG. 4A) or not substantially coplanar (as shown in FIG. 4B). The heat dissipative die 470 can be directly bonded to the second region 422 of the substrate 412 of the bottom component 410 (as shown in FIG. 4A), or a metallic bonding layer 471 can intervene (as shown in FIG. 4C). The active top die 450 can be separate and distinct from the heat dissipative die 470 (as shown, e.g., in FIG. 4A), or the active portion 453 of the top die 450E can be embedded in the same die that has a dissipative portion 455 (as shown, e.g., in FIG. 4E). The heat dissipative die 470 can be directly bonded to the substrate 412 of the bottom component 410 (as shown in FIG. 4A), or a dielectric bonding layer can intervene, as long as features are provided to reduce the obstruction to the flow of heat through the dielectric bonding layer. For example, as shown in FIG. 4F, thermally conductive vias 421 and/or pads 423 can transfer heat across the dielectric bonding layer 432F. As another example, as shown in FIG. 4I, the dielectric bonding layer can be thinned to form an ultrathin dielectric bonding layer 433. Additionally, the heat dissipative die 470 can have conductive vias 473 or pads 475 embedded therein (as shown in FIGS. 4F and 4G) but it need not have such embedded conductive features (as shown in FIG. 4A). As shown in FIG. 4G, a metallic heat spreader 480 can be directly bonded to the back side 404 of the top die 450 and heat dissipative die 470. As shown in FIG. 4H1, a top carrier 485 can be directly bonded to the back side 404 of the top die 450 and heat dissipative die 470. And as shown in FIG. 4H1, encapsulant 482 can be disposed laterally adjacent to any of the bottom component 410, the to die 450, or the heat dissipative die 470. These nonlimiting varieties of configurations can be combined as would be understood by the skilled artisan.

FIGS. 5A-5F depict a method of forming a bonded structure 500. Bonded structure 500 of FIG. 5F is similar to the bonded structure 400D of FIG. 4D, which is the same as bonded structure 300B of FIG. 3B.

FIG. 5A shows a bottom component 510 (e.g. processor wafer) disposed onto a carrier 506. FIG. 5A is the same as FIG. 2A, with reference numerals incremented from the 200s to the 500s. The bottom component 510 is polished so as to reach close to few microns (e.g. <10 microns) to the bottom tips of the TSVs 516 without exposing the TSVs.

FIGS. 5B-5E depict a selective backside TSV reveal process in which the substrate (e.g., silicon) recess is formed only at the area where top non-passivation (e.g., thermal) dies (e.g., active top die 550, shown in FIG. 5F) are to be bonded. FIG. 5B shows the structure of FIG. 5A after disposing a temporary masking layer 560 over the portion of the top surface 518 corresponding to the second region 522 of the substrate 512. The temporary masking layer 560 can comprise a resist, such a photoresist. The temporary masking layer 560 is disposed over the portion of the top surface 518 of the substrate 512 where, for example, the heat dissipative die 570 (in FIG. 5F) will eventually be bonded. The temporary masking layer 560 is patterned to expose the portion of the top surface 518 corresponding to the first region 520 of the substrate 512. The deposition of the temporary masking layer 560 leaves an exposed portion 562 of the top surface 518 of the substrate 512.

FIG. 5C shows the selectively recessed or etched structure in which the structure of FIG. 5B after the exposed portion 562 of the top surface 518 of the substrate 512 is etched or otherwise removed, forming a cavity 564 in the substrate 512 and effectively exposing the tips of TSVs 516 in the cavity 564 of the substrate 512. The process step shown in FIG. 5C is different from the process step shown in FIG. 2B. While the entirety of the top surface 218 of the substrate 212 is etched back in the process shown in FIG. 2B, only the exposed portion 562 of the top surface 518 of the substrate 512 is etched back in the selective TSV reveal process shown in FIG. 5C. Beneficially, the temporary masking layer 560 prevents the etchant from materially etching back the portion of the top surface 518 corresponding to, for example, the second region 522 of the substrate 512. After the exposed portion 562 is etched to form the cavity 564 in the substrate 512, the temporary masking layer 560 can be removed, and the backside of the substrate can be cleaned and dried.

FIG. 5D shows the structure of FIG. 5C after the deposition of one or more layers of barrier and/or liner 530 and a dielectric bonding layer 532 at the back side 504 of the bottom component 510. The dielectric bonding layer 532 fills the cavity 564 and coats the TSVs 516. For example, thin (e.g. <100 nm) silicon nitride layer can be deposited followed by one or more thicker layers of silicon oxide, silicon nitride, silicon oxynitride, silicon carbonitride, silicon oxycarbonitride, etc. In some embodiments, regardless of the nature of the material within the dielectric bonding layer 532, the concentration of composition of its constituent atoms, for example, silicon, oxygen, carbon and nitrogen etc. may vary within the thickness of the dielectric bonding layer 532.

FIG. 5E shows the structure of FIG. 5D after planarizing the back side 504 of the bottom component 510 to expose the TSVs 516. Unlike in the structure shown in FIG. 2D, the structure shown in FIG. 5E has a portion of the substrate 512 exposed at the back side 504. A first portion 566 of the exposed back side 504 of the bottom component 510, corresponding to the first region 520 of the substrate 512, comprises the dielectric bonding layer 532 and exposed surfaces of the plurality of TSVs 516 embedded therein. A second portion 568 of the exposed back side 504 of the bottom component 510 is adjacent to the first portion 566 of the exposed back side 504 of the bottom component 510. The second portion 568 of the exposed back side 504, corresponding to the second region 522 of the substrate 512, comprises the substrate 512. The first portion 566 and the second portion 568 of the exposed back side 504 of the bottom component 510 are polished and maintained to facilitate the bonding of the top die 550 and heat dissipative die 570 shown in FIG. 5F.

FIG. 5F shows bonded structure 500. FIG. 5F shows the structure of FIG. 5E after a top die 550 and a heat dissipative die 570 are directly bonded to the back side 504 of the bottom component 510 and the carrier 506 is removed. The top die 550 is hybrid bonded to the first portion 566 of the back surface of the bottom component 510. The heat dissipative die 570 of FIG. 5F can be different from the heat dissipative die 270 of FIG. 2E. Unlike the heat dissipative die 270 of FIG. 2E, which is directly bonded to the dielectric bonding layer 232; the heat dissipative die 570 of FIG. 5F is directly bonded to substrate 512. Beneficially, the lack of a disposed dielectric bonding layer between the heat dissipative die 570 and the substrate 512 creates a direct thermal pathway, unobstructed by thick layers of disposed thermally insulative material. In some embodiments, a thin layer of dielectric (e.g. <100 nm of oxide, nitride oxynitride, or carbonitride) may be deposited on the heat dissipative die 570. In some embodiments, thin native oxide (e.g. <10 nm) is formed on the exposed or bonding surface of the heat dissipative die 570.

In some embodiments, the top die 550 and the heat dissipative die 570 can be encapsulated or reconstituted. In some embodiments, a heat spreader or a top carrier (similar to, e.g., top carrier 485 shown in FIG. 4H1) can be bonded to the back side of the top die and the heat dissipative die.

In some embodiments, instead of the heat dissipative die 570, a heat dissipation wafer (not shown) can be bonded to the bottom component and subsequently patterned to remove the portions where non-thermal dissipation dies would be bonded to the bottom component. Such embodiments can be formed by starting with a structure similar to the structure of FIG. 5A. Instead of patterning a temporary masking layer 560 over the bottom component (as shown in FIG. 5B), a heat dissipative wafer can be bonded to the back side of the bottom component. Holes can be selectively etched or otherwise formed in the heat dissipative wafer to accommodate bonding a top die (e.g., top die 550) to the bottom component.

FIGS. 6A-6F depict a method of forming a bonded structure 600. Bonded structure 600 of FIG. 6F is similar to the bonded structure 400B of FIG. 4B. FIGS. 6A-6D show similar process steps depicted in FIGS. 2A-2D, with reference numerals incremented appropriately.

In FIG. 6A, the back surface 618 of the substrate 612 can have a surface roughness close to what is used for direct bonding surfaces. FIG. 6B shows the back surface 618 of the substrate 612 etched to make the TSVs 616 protrude from the back surface 618 of the substrate 612. The thickness of the etch shown in FIG. 6B can be, for example, between 500 nm and 1 micron. In some embodiments, the back surface 618 of the substrate 612 after being etched (shown in FIG. 6B) will have a surface roughness similar to its surface roughness before being etched (shown in FIG. 6A). In some embodiments, a wet etch of the substrate 612 can retain the surface roughness/smoothness of the pre-etched surface. In other embodiments, an optimized silicon dry etch can retain the surface roughness/smoothness of the pre-etched surface.

FIG. 6C shows the structure of FIG. 6B after a barrier layer 630 is deposited on the back surface 618 of the substrate 612 and exposed portions of the TSVs 616, and after a dielectric bonding layer 632 is deposited over the barrier layer 630. The barrier layer 630 is conformal over the TSVs 616. The barrier layer 630 can comprise layers and materials similar to those of dielectric layers 230 of FIG. 2C.

FIG. 6D shows a bottom component 610 disposed on a carrier 606, with a dielectric bonding layer 632 disposed onto the back side 604 of the substrate 612, the dielectric bonding layer 632 planarized to form a planarized top surface 636 and tips of TSVs 616 exposed. The exposed surface of the dielectric bonding layer 632 can be prepared for direct bonding by polishing, for example, by chemical mechanical polishing (CMP). The roughness of the polished bonding surfaces can be less than 30 Å rms. For example, the roughness of the bonding surfaces can be in a range of about 0.1 Å rms to 15 Å rms, 0.5 Å rms to 10 Å rms, or 1 Å rms to 5 Å rms. Polishing can also be tuned to leave the conductive features (e.g. exposed tips of TSVs 616) recessed relative to the field regions of the bonding layers 632.

FIG. 6E shows a temporary masking layer 660 disposed over the first portion 666 of the exposed back side 604 of the bottom component 610, corresponding to the first region 620 of the substrate 612. The temporary masking layer 660 is not disposed over the second portion 668 of the exposed back side 604 of the bottom component 610, corresponding to the second region 622 of the substrate 612. After the temporary masking layer 660 is disposed over the first portion 666 of the exposed back side 604 of the bottom component 610, the second portion 668 of the exposed back side 604 of the bottom component 610 is etched or otherwise removed. The temporary masking layer 660 prevents the first portion 666 of the exposed back side 604 from being materially etched. The second portion 668 of the exposed back side 604 is etched to thin or to remove the dielectric bonding layer 632 from the second portion 668 of the exposed back side 604. A thickness 637 of the dielectric bonding layer 632 after being etched can be between about 0 nm and 500 nm, between about 0 nm and 200 nm, between about 0 nm and 10 nm, between about 10 nm and 200 nm, between 20 nm and 200 nm, or between 20 nm and 100 nm. In some embodiments, the dielectric bonding layer 632 is completely removed from the second portion 668 of the exposed back side 604, exposing the barrier layer 630. In some embodiments, the barrier layer 630 comprises an etch stop. In some embodiments, the barrier layer 630 comprises Si₃N₄, silicon carbonitride or silicon oxynitride. In some embodiments, the barrier layer 630 has a thickness of between 20 nm and 200 nm, or between 25 nm and 100 nm, or between 30 nm and 70 nm. After etching, the temporary masking layer 660 can be removed, and the backside of the substrate can be cleaned and dried. Optionally, if the barrier layer 630 is exposed by the etch, the exposed barrier layer 630 can be removed. For example, the exposed barrier layer 630 can be removed if the exposed barrier layer 630 cannot be directly bonded, for example, to the heat dissipative die 670 shown in FIG. 6F. Optionally, the exposed surfaces of the first portion 666 and the second portion 668 of the back side 604 of the bottom component 610 can be activated without being polished. In the illustrated embodiment, the second portion 668 of the back side 604 of the bottom component 610 is not directly polished. The smoothness of the previously polished surface (e.g., planarized top surface 636, shown in FIG. 6D) is transferred or maintained to the second portion 668 of the back side 604 after etching (shown in FIG. 6E). The result of the processing shown in FIG. 6E is that the back side 604 of the bottom component 610 has two bonding surfaces. The two bonding surfaces are not co-planar with one another. One bonding surface, on the first portion 666 of the exposed back side 604, includes exposed surfaces of the plurality of TSVs 616. The other bonding surface, on the second portion 668 of the exposed back side 604, is substantially closer to the substrate 612 of the bottom component 610.

FIG. 6F shows bonded structure 600. FIG. 6F shows the structure of FIG. 6E after a top die 650 and a heat dissipative die 670 are directly bonded to the back side 604 of the bottom component 610 and the carrier 606 is removed. The top die 650 is bonded to the higher first portion 666 of the back surface of the bottom component 610. The heat dissipative die 670 is bonded to the lower second portion 668 of the back surface of the bottom component 610. Beneficially, the thinned or removed disposed dielectric bonding layer 632 between the heat dissipative die 670 and the substrate 612 creates a direct thermal pathway, unobstructed by thick layers of disposed thermally insulative material.

FIG. 6G shows the bonded structure 600 of FIG. 6F after being encapsulated and covered by a top carrier. The overall structure shown in FIG. 6G is similar to bonded structure 400H shown in FIG. 4H1. Laterally adjacent to the bottom component 610 is encapsulant 682A. The encapsulant 682A builds up the area laterally adjacent to the bottom component 610 up to the level of the first bond interface 638. The encapsulant 682A can comprise layers and materials similar to those of encapsulant 482A of FIG. 4H1.

Between the top die 650 and the heat dissipative die 670 is encapsulant 682B. In some embodiments, encapsulant 682B comprises the same or different material or materials as encapsulant 682A. In some embodiments, encapsulant 682B comprises different material as encapsulant 682A. The encapsulant 682B can also build up the area laterally adjacent to the heat dissipative die 670 up to the level of a second bond interface 688. FIG. 6G also shows a top carrier 685 directly bonded at the second bond interface 688. In some embodiments, the top carrier 685 can be laterally wider than the combined width of the heat dissipative die 670, the top die 650, and the encapsulant 682B. In some embodiments, the top carrier 485 can have the same width as the combined width of the heat dissipative die 670, the top die 650, and the encapsulant 682B. In some embodiments, the top carrier 685 can be less wide than the combined width of the heat dissipative die 670, the top die 650, and the encapsulant 682B. In some embodiments, the top carrier 685 can be directly bonded (e.g., uniformly directly bonded) to underlying layers. In some embodiments, the top carrier 685 can be adhered to the underlying layers, for example, with a thermal interface material (i.e., TIM). In some embodiments, the top carrier 685 can be direct bonded to the underlying layers including exposed surfaces of die 670 and 650 along with reconstituted dielectric or encapsulation 682B. In some other embodiments, the top carrier 685 can be direct bonded to the underlying bonding layer formed on the exposed surfaces of die 670 and 650 along with reconstituted dielectric or encapsulation 682B. In some embodiments, a heat spreader (e.g. copper heat spreader) can be adhered to the top carrier 685, for example, with a thermal interface material (i.e., TIM), as shown in FIG. 4H2. In some other embodiments, another carrier (e.g. liquid cooling cavity die) is direct bonded to the top carrier 485. In some embodiments, after encapsulant is added, the bonded structure can be singulated into various multi-layer dies. The structure of FIG. 6G is annotated with the direct thermal pathway 699, showing the unobstructed dissipation of heat from the substrate 612 of the bottom component 610 and adjacent encapsulant 682A, vertically up through the heat dissipative die 670 and adjacent encapsulant 682B, to the top carrier 685. Beneficially, no deposited dielectric or other deposited insulating material obstructs the direct thermal pathway 699.

In some embodiments, the top die and the heat dissipative die can be encapsulated or reconstituted. In some embodiments, a heat spreader or a top carrier can be bonded to the back side of the top die and the heat dissipative die.

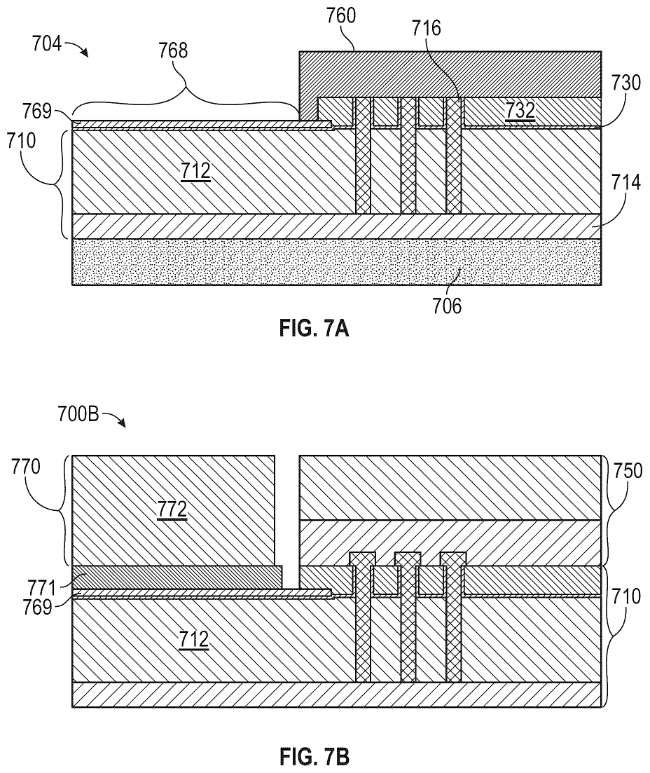

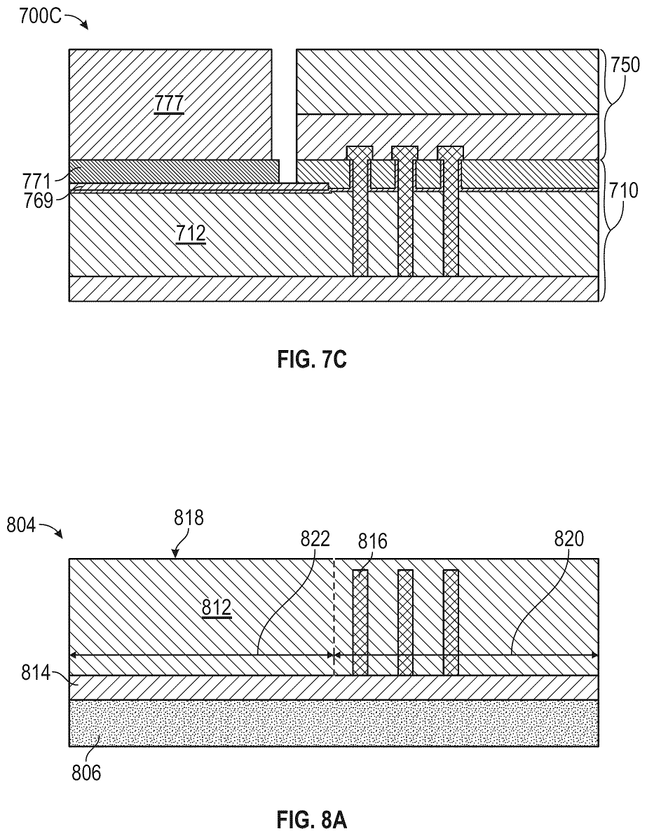

FIGS. 6A-6F display a method of forming a bonded structure 600 in which the dielectric bonding layer 632 is substantially thinned or removed from the portion of the back side 604 of the bottom component 610 to which a dissipative component (e.g. the heat dissipative die 670) is configured to be bonded. FIGS. 7A-7C display methods of forming other embodiments of bonded structures (e.g., bonded structures 700B of FIG. 7B and bonded structure 700C of FIG. 7C) in which the dielectric bonding layer is substantially thinned or removed from the portion of the back side of the bottom component to which a dissipative component is configured to be bonded. However, whereas the dissipative feature of FIG. 6F (i.e., heat dissipative die 670) is directly bonded to bottom component 610 without any intervening adhesive, the dissipative features of FIGS. 7B and 7C are bonded to the bottom component 710 with an intervening metallic bonding layer 771.

FIG. 7A is similar to FIG. 6E. Unlike the structure shown in FIG. 6E, however, the structure shown in FIG. 7A has a metal seed layer 769 disposed over the second portion 768 of the exposed back side 704 of the bottom component 710. Depositing the metal seed layer 769 facilitates subsequent deposition of a metallic bonding layer 771 (shown in FIGS. 7B and 7C). However, depositing the metal seed layer 769 is optional.

FIGS. 7B and 7C show two different embodiments of bonded structures with two different types of dissipative features bonded to the substrate 712 with an intervening metallic bonding layer 771.

FIG. 7B depicts bonded structure 700B, which is the same as bonded structure 400C shown in FIG. 4C. FIG. 7B shows the structure from FIG. 7A after the temporary masking layer 760 has been removed, top die 750 is directly bonded to dielectric bonding layer 732 without an intervening adhesive, and a heat dissipative die 770 is bonded to the substrate 712 with an intervening metallic bonding layer 771. The heat dissipative die 770 comprises a substrate 772, which can include a semiconductor material, such as silicon. The semiconductor material is bonded to the bottom component 710 with an intervening metallic bonding layer 771. In some embodiment, heat dissipative die 770 can be processed (e.g. metallized) so as to allow joining via solder, etc. to the bottom component 710.

FIG. 7C depicts bonded structure 700C. Bonded structure 700C of FIG. 7C is the similar to the bonded structure 700B of FIG. 7B but with different dissipative features. In bonded structure 700B of FIG. 7B, the dissipative feature is heat dissipative die 770. As discussed above, heat dissipative die 770 can comprise a semiconductor material, such as silicon. In bonded structure 700C of FIG. 7C, the dissipative feature is thermal conduit die 777. Thermal conduit die 777 can comprise materials or systems similar to those described in the heat spreader 480 described with FIG. 4G above.

FIGS. 8A-8F depict a method of forming a bonded structure 800. Bonded structure 800 of FIG. 8F is the same as bonded structure 400I of FIG. 4I.

FIG. 8A shows a bottom component 810 disposed onto a carrier 806. FIG. 8A is the same as FIG. 2A, with reference numerals incremented from the 200s to the 800s.

FIG. 8B shows the structure of FIG. 8A after the back surface 818 of the substrate 812 has thinned via a grinding and/or polishing process to expose the TSVs 816 at the back side 804 of the substrate 812. In some embodiments, the grinding and/or polishing step can comprise CMP processing. In some embodiments, the CMP processing can include a CMP slurry having more than 100 ppm BTA. The grinding and/or polishing step of FIG. 8B can be performed below 30° C., below 25° C., or below 20° C. Exposing TSV tips by CMP rather than etching is discussed in U.S. publication 2022/0246497, incorporated herein by reference.

FIG. 8C shows the structure of FIG. 8B after the back side 804 of the substrate 812 is selectively etched by a thickness 813 to form protruded TSVs 816 on the back side 804 of the substrate 812. As discussed in U.S. application Ser. No. 17/646,135, etching step of FIG. 8C can remove any material of the substrate 812 that might have been contaminated from smeared TSV metal during the grinding/polishing step of FIG. 8B. In some embodiments, the width (e.g., diameter) 815 of the TSVs 816 can be between 0.5 microns and 10 microns, between 0.5 microns and 2 microns, between 1 micron and 8 microns, between 2 microns and 4 microns, or around 3 microns. In some embodiments, the thickness (or depth) 813 of the etch can be less than about 1 micron. For example, the thickness (or depth) 813 of the etch can be between about 50 nm and 600 nm, between 100 nm and 500 nm, between 200 nm and 500 nm, between 300 nm and 450 nm, or between 350 nm and 450 nm.

FIG. 8D shows the structure of FIG. 8C after deposition of one or more layers of liner (not shown) and a thin dielectric bonding layer 833 over the back side 804 of the substrate 812 and protruding TSVs 816. As described herein and shown in FIGS. 8E and 8F, the thin dielectric bonding layer 833 is beneficially thin enough to not substantially obstruct the flow of heat. At least for this reason, the thin dielectric bonding layer 833 can be deposited using thin layer deposition.

FIG. 8E shows the structure of FIG. 8D after the back side 804 of the ultrathin dielectric bonding layer 833 is planarized to form a sufficiently smooth surface for direct bonding. The ultrathin dielectric bonding layer 833 is a deposited oxide and thus has a low thermal conductivity. However, the planarized ultrathin dielectric bonding layer 833 is thin enough to not substantially obstruct the flow of heat. In some embodiments, the thickness 835 of the planarized ultrathin dielectric bonding layer 833 can be between about 2 nm and 10 nm, between about 10 nm and 100 nm, between 50 nm and 200 nm, between 50 nm and 500 nm, between 100 nm and 450 nm, or between 200 nm and 400 nm. An aspect ratio can be defined as the width 815 of the TSVs 816 to the thickness 835 of the planarized ultrathin dielectric bonding layer 833. If the width 815 of the TSVs 816 is about 3 microns and the thickness 835 of the ultrathin dielectric bonding layer 833 is about 500 nm, then the aspect ratio is about 6. In some embodiments, the aspect ratio is at least 6.

FIG. 8F shows bonded structure 800. FIG. 8F shows the structure of FIG. 8E after a top die 550 and a heat dissipative die 870 are directly bonded to the back side 804 of the uniform ultrathin dielectric bonding layer 833 and the carrier 506 is removed. As depicted in FIGS. 5F, 6F, 7B, and 7C, the top die 850 is directly bonded such that the conductive features (e.g., conductive pads 856) of the top die 850 are directly bonded to the conductive features (e.g., TSVs 816) of the bottom component 810. As depicted in FIGS. 5F and 6F, the heat dissipative die 870 is directly bonded over a portion of the substrate 812 without TSVs embedded therein.

A direct thermal pathway is formed between the substrate 812 of the bottom component 810 and the heat dissipative die 870. Unlike the dielectric bonding layer 232 shown in FIG. 2E, the uniform ultrathin dielectric bonding layer 833 is thin enough to not substantially obstruct the flow of heat.

In one aspect, a bonded structure includes an element, a first die, and a second die. The element has a bonding surface, the bonding surface having a dielectric region and a first semiconductor region adjacent to the dielectric region. The first die is directly bonded to the dielectric region of the element without an intervening adhesive. The second die includes a second bonding surface having a second semiconductor region. The second semiconductor region is directly bonded to the first semiconductor region of the element without an intervening adhesive and without an intervening deposited dielectric material.

In some embodiments, the element includes a semiconductor substrate with a deposited dielectric bonding layer over the semiconductor substrate in the dielectric region. The first die is directly bonded to the deposited dielectric bonding layer, and the second die is directly bonded to the semiconductor substrate. In some embodiments, the first semiconductor region of the semiconductor substrate includes a non-deposited native oxide layer. In some embodiments, the element further includes a bulk semiconductor with a first side and a second side opposite the first side. The element also further includes a dielectric bonding layer with a first side and a second side opposite the first side, in which the dielectric bonding layer is deposited onto a portion of the second side of the bulk semiconductor such that the first side of the dielectric bonding layer faces the second side of the bulk semiconductor. In some embodiments, the second side of the dielectric bonding layer comprises the dielectric region of the bonding surface of the element. In some embodiments, the second side of the bulk semiconductor comprises the semiconductor region of the bonding surface of the element. In some embodiments, the semiconductor region of the bonding surface is substantially coplanar with the first side of the dielectric bonding layer. In some embodiments, a bond interface between the first die and the dielectric region of the bonding surface of the element is at a different vertical elevation relative to a bond interface between the second die and the semiconductor region of the bonding surface of the element. In some embodiments, a difference in vertical elevation substantially matches a thickness of the dielectric bonding layer of the element. In some embodiments, the semiconductor region of the bonding surface is substantially coplanar with the second side of the dielectric bonding layer. In some embodiments, a bond interface between the first die and the dielectric region of the bonding surface of the element is substantially coplanar with a bond interface between the second die and the semiconductor region of the bonding surface of the element. In some embodiments, the element further comprises wiring layers on the first side of the bulk semiconductor, and the first die comprises integrated circuits that are in electrical connection with the wiring layers of the element. In some embodiments, the element further includes a plurality of electrically conductive contact features embedded in the dielectric bonding layer. In some embodiments, the contact features are in electrical communication with the integrated circuits of the first die. In some embodiments, the element further includes electrically conductive vias extending from the conductive contact features at least partially into the bulk semiconductor of the element. In some embodiments, the conductive vias are in electrical communication with the conductive contact features. In some embodiments, the bonded structure further includes a barrier layer disposed between the dielectric bonding layer of the element and the plurality of electrically conductive vias. In some embodiments, the second die is a dummy die. In some embodiments, the second die is bonded to the semiconductor region of the bonding surface of the element using soldering or metallic bonding. In some embodiments, the semiconductor material of the second die comprises silicon. In some embodiments, the bulk semiconductor of the element comprises silicon. In some embodiments, a thermal conductivity of the second die is greater than 10 W/mK. In some embodiments, a thermal conductivity of the second die is greater than 100 W/mK. In some embodiments, a thermal conductivity of the second die is greater than 200 W/mK. In some embodiments, the second bonding surface of the second die comprises a non-deposited dielectric layer that has a thickness of less than 15 nm. In some embodiments, the thickness of the non-deposited dielectric layer is less than 10 nm. In some embodiments, the thickness of the non-deposited dielectric layer is less than 5 nm. In some embodiments, the thickness of the non-deposited dielectric layer of the second die is less than a thickness of the dielectric bonding layer of the element. In some embodiments, the non-deposited dielectric layer of the second die comprises a native dielectric layer. In some embodiments, the first semiconductor region of the bonding surface of the element comprises a non-deposited dielectric layer that has a thickness of less than 15 nm. In some embodiments, the thickness of the non-deposited dielectric layer is less than 10 nm. In some embodiments, the thickness of the non-deposited dielectric layer is less than 5 nm. In some embodiments, the non-deposited dielectric layer of the second die comprises a native dielectric layer. In some embodiments, the second bonding surface of the second die comprises a non-deposited dielectric layer that has a thickness of less than 15 nm. In some embodiments, the first die is laterally separated the second die by a reconstituted dielectric. In some embodiments, the bonded structure further includes a barrier layer disposed between the dielectric bonding layer of the element and the bulk semiconductor of the element. In some embodiments, the bonded structure further includes a heat spreading element thermally coupled to a back side of the second die opposite the element.

In another aspect, a bonded structure includes a first element and a second element. The first element has a first bonding surface. The first bonding surface has a dielectric region and a semiconductor region laterally spaced from the dielectric region. The second element has a second bonding surface. The second bonding surface has a dielectric region and a semiconductor region laterally spaced from the dielectric region. The first element is directly bonded to the second element without an intervening adhesive, such that the dielectric region of the first bonding surface is directly bonded to the dielectric region of the second bonding surface, and such that the semiconductor region of the first bonding surface is directly bonded to the semiconductor region of the second bonding surface without an intervening deposited dielectric material.

In some embodiments, the bonded structure further includes electronic components embedded within the dielectric region of the second element. In some embodiments, the bonded structure further includes electrically conductive pads embedded within the dielectric region of the second element, the pads in electrical communication with the electronic components. In some embodiments, the bonded structure further includes electrically conductive contact features embedded within the dielectric region of the first element, the conductive contact features in electrical communication with the conductive pads. In some embodiments, the bonded structure further includes electrically conductive vias extending from the conductive contact features at least partially into the first element, the conductive vias in electrical communication with the conductive contact features. In some embodiments, the semiconductor region of the first element comprises silicon, and the semiconductor region of the second element comprises silicon. In some embodiments, a bond interface between the semiconductor region of the first bonding surface and the semiconductor region of the second bonding surface comprises a non-deposited native oxide.

In another aspect, a bonded structure includes an element, an active die, and a dummy die. The element includes a bulk semiconductor with a first side and a second side opposite the first side. The element also includes wiring layers on the first side of the bulk semiconductor. The element also includes a dielectric bonding layer disposed on the second side of the bulk semiconductor. The dielectric bonding layer has a bonding surface with a first bonding region and a second bonding region laterally spaced from the first bonding region. The element also includes a plurality of electrically conductive vias embedded in the second bonding region of the dielectric bonding layer and extending at least partially into the bulk semiconductor of the element. The active die is hybrid bonded to the first bonding region. The dummy die is directly bonded to the second bonding region. The dummy die includes at least one electrically conductive via extending at least partially into a bulk semiconductor region of the dummy die.

In some embodiments, the dummy die includes a fourth plurality of electrically conductive contact features embedded in a surface of the bulk semiconductor of the dummy die. In some embodiments, the dummy die also includes a third plurality of electrically conductive vias extending from the fourth plurality of contact features partially into the bulk semiconductor of the dummy die. In some embodiments, the dummy die is directly bonded to the second bonding region of the element such that the fourth plurality of conductive contact features of the dummy die are directly bonded to the plurality of conductive contact features of the second bonding region without an intervening adhesive, and such that the bulk semiconductor of the dummy die is directly bonded to the second bonding region without an intervening adhesive. In some embodiments, the bulk semiconductor of the dummy die comprises silicon. In some embodiments, a second plurality of electrically conductive vias are embedded in the first bonding region of the dielectric bonding layer and extend through the bulk semiconductor to be in electrical communication with the wiring layers of the element. In some embodiments, the plurality of conductive vias of the element extend only partially through the bulk semiconductor of the element and are not in electrical communication with the wiring layers of the element. In some embodiments, the bulk semiconductor of the dummy die comprises a non-deposited dielectric layer where it is bonded to the element, wherein the non-deposited dielectric layer has a thickness of less than 15 nm. In some embodiments, the non-deposited dielectric layer has a thickness of less than 10 nm. In some embodiments, the non-deposited dielectric layer has a thickness of less than 5 nm. In some embodiments, the bonded structure further includes a cooling element thermally coupled to the dummy die opposite the element.

In another aspect, a method of forming a bonded structure is provided. The method includes providing an element, the element having a bonding surface with a dielectric region and a first semiconductor region laterally spaced from and substantially coplanar with the dielectric region. The method also includes providing a first die directly bonded to the dielectric region of the element without an intervening adhesive. The method also includes providing a second die comprising a second bonding surface having a second semiconductor region, the second semiconductor region being bonded to the first semiconductor region of the element without an intervening deposited dielectric material.

In some embodiments, providing an element includes providing a bulk semiconductor substrate with a surface, the surface having a first region and a second region laterally spaced from the first region. In some embodiments, providing an element also includes providing a plurality of conductive vias embedded in the first region of the surface of the bulk semiconductor substrate. In some embodiments, providing an element also includes forming a cavity in the first region of the surface of the bulk semiconductor substrate, wherein the plurality of conductive vias are revealed and protrude within the cavity. In some embodiments, providing an element also includes depositing a dielectric bonding layer into the cavity and forming the bonded surface of the element. In some embodiments, forming the bonded surface of the element includes polishing the dielectric bonding layer to form the dielectric region of the bonding surface, wherein the plurality of conductive vias are exposed within the dielectric region of the bonding surface. In some embodiments, forming the bonded surface of the element also includes polishing the second region of the surface of the bulk semiconductor substrate to form the first semiconductor region of the bonding surface. In some embodiments, forming a cavity in the first region of the surface of the bulk semiconductor substrate includes covering the second region of the surface of the bulk semiconductor substrate with a temporary layer, etching the first region of the surface of the bulk semiconductor to form the cavity in the bulk semiconductor substrate, and removing the temporary layer. In some embodiments, the temporary layer comprises resist. In some embodiments, the method further includes, before depositing a dielectric bonding layer into the cavity, depositing a barrier layer over at least the cavity in the bulk semiconductor substrate and the protruding conductive vias therein. In some embodiments, the element comprises wiring layers on a second side of the bulk semiconductor substrate, the second side of the bulk semiconductor substrate opposite the surface of the bulk semiconductor substrate, and wherein the plurality of conductive vias are in electrical communication with the wiring layers. In some embodiments, the second die is a dummy die. In some embodiments, the dummy die comprises silicon. In some embodiments, the dummy die comprises a non-deposited dielectric layer where it is bonded to the semiconductor region, wherein the non-deposited dielectric layer has a thickness of less than 15 nm. In some embodiments, the second die is directly bonded to the semiconductor region without an intervening adhesive. In some embodiments, the second die is bonded to the semiconductor bonding region using soldering or metallic bonding. In some embodiments, the bulk semiconductor substrate of the element comprises silicon. In some embodiments, the first die comprises an active die. In some embodiments, the active die includes electronic components embedded within the active die and a dielectric surface with conductive contact features embedded thereon, the contact features in electrical communication with the electronic components. In some embodiments, direct bonding a first die to the dielectric bonding region without an intervening adhesive comprises forming an electrical connection between the electronic components of the active die and the conductive vias of the element.

In another aspect, a method of forming a bonded structure is provided. The method includes providing a bulk semiconductor substrate having a surface with a first region and a second region laterally spaced from the first region. The method further includes providing a dielectric bonding layer over the first region of the surface. The method further includes providing an active die directly bonded onto the dielectric bonding layer. The method further includes providing a dummy die onto the second region of the surface of the bulk semiconductor substrate without an intervening deposited dielectric material.

In some embodiments, an interface between the active die and the dielectric bonding layer is not substantially coplanar with an interface between the dummy die and the second region of the surface of the bulk semiconductor substrate. In some embodiments, providing a dielectric bonding layer over the first region of the surface includes providing a plurality of conductive vias embedded in the first region of the surface of the bulk semiconductor substrate. In some embodiments, providing a dielectric bonding layer over the first region of the surface further includes etching the surface of the bulk semiconductor substrate, such that the plurality of conductive vias protrude above the etched surface, depositing a dielectric bonding material over the surface and covering the plurality of conductive vias protruding above the etched surface, polishing the dielectric bonding material to expose the plurality of conductive vias, covering the dielectric bonding material over the first region of the surface with a temporary layer, removing the dielectric bonding material from over the second region of the surface, and removing the temporary layer. In some embodiments, the temporary layer comprises resist. In some embodiments, the method further includes, before depositing a dielectric bonding material, depositing a barrier layer over the surface and covering the plurality of conductive vias protruding above the etched surface. In some embodiments, the bonded structure comprises wiring layers on a second side of the bulk semiconductor substrate, the second side of the bulk semiconductor substrate opposite the surface of the bulk semiconductor substrate, and wherein the plurality of conductive vias are in electrical communication with the wiring layers. In some embodiments, the bulk semiconductor substrate comprises a processor device. In some embodiments, the active die comprises a memory die. In some embodiments, providing a dummy die onto the second region of the surface of the bulk semiconductor substrate comprises directly bonding the dummy die onto the second region of the surface of the bulk semiconductor substrate, without an intervening adhesive. In some embodiments, providing a dummy die onto the second region of the surface of the bulk semiconductor substrate comprises bonding the dummy die onto the second region of the surface of the bulk semiconductor substrate with an intervening metallic bonding layer. In some embodiments, the dummy die comprises a bulk semiconductor. In some embodiments, the dummy die comprises a bulk semiconductor and a non-deposited dielectric layer where the dummy die is provided onto the second region of the surface of the bulk semiconductor substrate, wherein the non-deposited dielectric layer has a thickness of less than 15 nm. In some embodiments, a thickness separating the second region of the surface of the bulk semiconductor substrate from the bulk semiconductor of the dummy die is less than 1 micron. In some embodiments, a thickness separating the second region of the surface of the bulk semiconductor substrate from the bulk semiconductor of the dummy die is less than 100 nm. In some embodiments, a thickness separating the second region of the surface of the bulk semiconductor substrate from the bulk semiconductor of the dummy die is less than 10 nm. In some embodiments, the bulk semiconductor substrate comprises silicon. In some embodiments, the active die includes electronic components embedded within the active die and a dielectric surface with conductive contact features embedded thereon, the contact features in electrical communication with the electronic components. In some embodiments, direct bonding a first die to the first region of the dielectric surface without an intervening adhesive comprises forming an electrical connection between the electronic components of the active die and the plurality of conductive vias.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A bonded structure comprising:
an element with a bonding surface, the bonding surface having a dielectric region and a first semiconductor region adjacent to the dielectric region;
a first die directly bonded to the dielectric region of the element without an intervening adhesive; and
a second die comprising a second bonding surface having a second semiconductor region, the second semiconductor region being directly bonded to the first semiconductor region of the element without an intervening adhesive and without an intervening deposited dielectric material.

2. The bonded structure of claim 1, wherein the element comprises a semiconductor substrate with a deposited dielectric bonding layer over the semiconductor substrate in the dielectric region, the first die directly bonded to the deposited dielectric bonding layer, and the second die directly bonded to the semiconductor substrate.

3. (canceled)

4. The bonded structure of claim 1, wherein the element comprises:
a bulk semiconductor with a first side and a second side opposite the first side; and
a dielectric bonding layer with a first side and a second side opposite the first side, the dielectric bonding layer deposited onto a portion of the second side of the bulk semiconductor such that the first side of the dielectric bonding layer faces the second side of the bulk semiconductor,
wherein the second side of the dielectric bonding layer comprises the dielectric region of the bonding surface of the element, and
wherein the second side of the bulk semiconductor comprises the semiconductor region of the bonding surface of the element.

5. The bonded structure of claim 4, wherein the semiconductor region of the bonding surface is substantially coplanar with the first side of the dielectric bonding layer.

6. The bonded structure of claim 4, wherein a bond interface between the first die and the dielectric region of the bonding surface of the element is at a different vertical elevation relative to a bond interface between the second die and the semiconductor region of the bonding surface of the element.

7. The bonded structure of claim 6, wherein a difference in vertical elevation substantially matches a thickness of the dielectric bonding layer of the element.

8. The bonded structure of claim 4, wherein the semiconductor region of the bonding surface is substantially coplanar with the second side of the dielectric bonding layer.

9. The bonded structure of claim 1, wherein a bond interface between the first die and the dielectric region of the bonding surface of the element is substantially coplanar with a bond interface between the second die and the semiconductor region of the bonding surface of the element.

10. The bonded structure of claim 4, wherein the element further comprises wiring layers on the first side of the bulk semiconductor, and wherein the first die comprises integrated circuits that are in electrical connection with the wiring layers of the element.

11. The bonded structure of claim 10, wherein the element further comprises:
a plurality of electrically conductive contact features embedded in the dielectric bonding layer, the conductive contact features in electrical communication with the integrated circuits of the first die; and
electrically conductive vias extending from the conductive contact features at least partially into the bulk semiconductor of the element, the conductive vias in electrical communication with the conductive contact features.

12. (canceled)

13. The bonded structure of claim 1, wherein the second die is a dummy die.

14. (canceled)

15. The bonded structure of claim 1, wherein the semiconductor material of the second die comprises silicon.

16. (canceled)

17. The bonded structure of claim 1, wherein a thermal conductivity of the second die is greater than 10 W/mK.

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. A bonded structure comprising:
a first element with a first bonding surface, the first bonding surface having a dielectric region and a semiconductor region laterally spaced from the dielectric region; and
a second element with a second bonding surface, the second bonding surface having a dielectric region and a semiconductor region laterally spaced from the dielectric region,
wherein the first element is directly bonded to the second element without an intervening adhesive, such that the dielectric region of the first bonding surface is directly bonded to the dielectric region of the second bonding surface, and such that the semiconductor region of the first bonding surface is directly bonded to the semiconductor region of the second bonding surface without an intervening deposited dielectric material.

34. The bonded structure of claim 33, further comprising:
electronic components embedded within the dielectric region of the second element;
electrically conductive pads embedded within the dielectric region of the second element, the pads in electrical communication with the electronic components;
electrically conductive contact features embedded within the dielectric region of the first element, the contact features in electrical communication with the conductive pads; and
electrically conductive vias extending from the conductive contact features at least partially into the first element, the conductive vias in electrical communication with the conductive contact features.

35. The bonded structure of claim 33, wherein the semiconductor region of the first element comprises silicon, and wherein the semiconductor region of the second element comprises silicon.

36. (canceled)

37. A bonded structure comprising:
an element including:
a bulk semiconductor with a first side and a second side opposite the first side;
wiring layers on the first side of the bulk semiconductor;
a dielectric bonding layer disposed on the second side of the bulk semiconductor, the dielectric bonding layer having a bonding surface with a first bonding region and a second bonding region laterally spaced from the first bonding region; and
a plurality of electrically conductive vias embedded in the second bonding region of the dielectric bonding layer and extending at least partially into the bulk semiconductor of the element;
an active die hybrid bonded to the first bonding region; and
a dummy die directly bonded to the second bonding region, the dummy die comprising at least one electrically conductive via extending at least partially into a bulk semiconductor region of the dummy die.

38. The bonded structure of claim 37, wherein the dummy die comprises:
a fourth plurality of electrically conductive contact features embedded in a surface of the bulk semiconductor of the dummy die; and
a third plurality of electrically conductive vias extending from the fourth plurality of contact features partially into the bulk semiconductor of the dummy die,
wherein the dummy die is directly bonded to the second bonding region of the element such that the fourth plurality of conductive contact features of the dummy die are directly bonded to the plurality of conductive contact features of the second bonding region without an intervening adhesive, and such that the bulk semiconductor of the dummy die is directly bonded to the second bonding region without an intervening adhesive.

39. (canceled)

40. The bonded structure of claim 37, wherein a second plurality of electrically conductive vias are embedded in the first bonding region of the dielectric bonding layer and extend through the bulk semiconductor to be in electrical communication with the wiring layers of the element.

41. The bonded structure of claim 37, wherein the plurality of conductive vias of the element extend only partially through the bulk semiconductor of the element and are not in electrical communication with the wiring layers of the element.

42. (canceled)

43. (canceled)

44. (canceled)

45. (canceled)

46-78. (canceled)
